(19) United States
(12) Patent Application Publication
(10) Pub. No.: US 2025/0180188 A1
(43) Pub. Date: Jun. 5, 2025

(54) LIGHT-EMITTING MODULE

(71) Applicant: NICHIA CORPORATION, Anan-shi (JP)

(72) Inventor: Norimasa YOSHIDA, Komatsushima-shi (JP)

(73) Assignee: NICHIA CORPORATION, Anan-shi (JP)

(21) Appl. No.: 19/052,539

(22) Filed: Feb. 13, 2025

Related U.S. Application Data
(63) Continuation of application No. PCT/JP2023/028973, filed on Aug. 8, 2023.

(30) Foreign Application Priority Data
Aug. 18, 2022 (JP) 2022-130690
May 17, 2023 (JP) 2023-081740
Jul. 14, 2023 (JP) 2023-116250

(51) Int. Cl. F21V 14/06; F21Y 105/12; F21Y 113/10; F21Y 115/10; F21Y 115/30; G03B 15/05; H05B 45/20; H05B 47/155; H05B 47/16

(52) U.S. Cl. CPC F21V 14/06; G03B 15/05; H05B 45/20; H05B 47/155; H05B 47/16; F21Y 2105/12; F21Y 2113/10; F21Y 2115/10; F21Y 2115/30

(57) ABSTRACT

A light-emitting module includes: a light source including a plurality of light-emitting parts having respective light-emitting surfaces and including: at least one first light-emitting part configured to emit light having a first chromaticity, and at least one second light-emitting part configured to emit light having a second chromaticity different from the first chromaticity; a lens configured to transmit light from the light source; an actuator configured to change at least one of a relative position between the light source and the lens in a direction intersecting an optical axis of the lens or a relative inclination of the optical axis of the lens with respect to a corresponding one of the light-emitting surfaces; and a controller configured to control light emission of each of the plurality of light-emitting parts and operation of the actuator.

### CROSS-REFERENCE TO RELATED APPLICATIONS

This application is a continuation of International Application No. PCT/JP2023/028973, filed on Aug. 8, 2023 and designating the U.S., which claims priority to Japanese Patent Application No. 2022-130690, filed on Aug. 18, 2022, Japanese Patent Application No. 2023-081740, filed on May 17, 2023, and Japanese Patent Application No. 2023-116250, filed on Jul. 14, 2023. The contents of these applications are incorporated herein by reference in their entirety.

### BACKGROUND

### 1. Technical Field

The present disclosure relates to a light-emitting module.

### 2. Description of Related Art

Light-emitting modules including light-emitting diodes and the like have been widely used. For example, Japanese Patent Publication No. 2008-186777 describes a configuration in which a plurality of phosphor members are disposed in a path of light emitted from each of a plurality of light-emitting elements.

### SUMMARY

There is a demand for light-emitting modules having a color adjusted to a predetermined color.

An object of certain embodiments of the present disclosure is to provide a light-emitting module that can emit light having a color adjusted to a predetermined color.

A light-emitting module according to one embodiment of the present disclosure includes: a light source including a plurality of light-emitting parts having respective light-emitting surfaces and including at least one first light-emitting part configured to emit light having a first chromaticity, and at least one second light-emitting part configured to emit light having a second chromaticity different from the first chromaticity; a lens configured to transmit light from the light source; an actuator configured to change at least one of a relative position between the light source and the lens in a direction intersecting an optical axis of the lens or a relative inclination of the optical axis of the lens with respect to a corresponding one of the light-emitting surfaces; and a controller configured to control light emission of each of the plurality of light-emitting parts and operation of the actuator. The controller is configured to perform control such that: the plurality of light-emitting parts are caused to emit light while at least one of the relative position or the relative inclination is changed by the actuator, and a position in an irradiation region on which light emitted from the first light-emitting part and transmitted through the lens is incident before a change in at least one of the relative position or the relative inclination and a position in the irradiation region on which light emitted from the second light-emitting part and transmitted through the lens is incident after the change in the at least one of the relative position or the relative inclination at least partially overlap with each other.

A light-emitting module according to one embodiment of the present disclosure includes: a light source including a plurality of light-emitting parts having respective light-emitting surfaces and including at least one first light-emitting part configured to emit light having a first chromaticity, and at least one second light-emitting part configured to emit light having a second chromaticity different from the first chromaticity; a lens configured to transmit light from the light source; an actuator configured to change at least one of a relative position between the light source and the lens in a direction intersecting an optical axis of the lens or a relative inclination of the optical axis of the lens with respect to a corresponding one of the light-emitting surfaces; and a controller configured to control light emission of each of the plurality of light-emitting parts and operation of the actuator. The controller is configured to perform control such that: the plurality of light-emitting parts are caused not to emit light while one of the relative position or the relative inclination is changed by the actuator, and a position in an irradiation region on which light emitted from the first light-emitting part and transmitted through the lens is incident before a change in at least one of the relative position or the relative inclination and a position in the irradiation region on which light emitted from the second light-emitting part and transmitted through the lens is incident after the change in the at least one of the relative position or the relative inclination at least partially overlap with each other.

### BRIEF DESCRIPTION OF THE DRAWINGS

FIG. 1 is a schematic top view illustrating an example configuration of a light-emitting module according to a first embodiment;

FIG. 2 is a schematic cross-sectional view taken along line II-II of FIG. 1;

FIG. 3 is a schematic cross-sectional view taken along line III-III of FIG. 1;

FIG. 4 is a schematic cross-sectional view illustrating the light-emitting module after a lens is moved from the state of FIG. 3;

FIG. 5 is a block diagram illustrating an example functional configuration of a controller of the light-emitting module of FIG. 1;

FIG. 6 is a timing chart illustrating a first example of the operation of the light-emitting module of FIG. 1;

FIG. 7 is a timing chart illustrating a second example of the operation of the light-emitting module of FIG. 1;

FIG. 8A is a diagram illustrating an example of irradiation light from the light-emitting module of FIG. 1 in a state A;

FIG. 8B is a diagram illustrating an example of irradiation light from the light-emitting module of FIG. 1 in a state B;

FIG. 8C is a diagram illustrating an example of mixed-color light of the irradiation light of FIG. 8A and the irradiation light of FIG. 8B;

FIG. 9 is a schematic cross-sectional view illustrating an example configuration of a light-emitting module according to a first modification of the first embodiment;

FIG. 10A is a schematic cross-sectional view of the light-emitting module after the inclination angle of the optical axis of the lens is changed from the state of FIG. 9;

FIG. 10B is a schematic cross-sectional view illustrating an example configuration of a light-emitting module according to a second modification of the first embodiment;

FIG. 10C is a schematic cross-sectional view illustrating an example configuration of a light-emitting module according to a third modification of the first embodiment;

FIG. 11 is a schematic top view illustrating an example configuration of a light-emitting module according to a second embodiment;

FIG. 12 is a schematic cross-sectional view taken along line XII-XII of FIG. 11;

FIG. 13 is a schematic cross-sectional view of the light-emitting module after the lens is moved from the state of FIG. 12;

FIG. 14A is a diagram illustrating an example of irradiation light from the light-emitting module of FIG. 11 in a state E;

FIG. 14B is a diagram illustrating an example of irradiation light from the light-emitting module of FIG. 11 in a state F;

FIG. 14C is a diagram illustrating an example of mixed-color light obtained by mixing the irradiation light of FIG. 14A and the irradiation light of FIG. 14B;

FIG. 15A is a diagram illustrating an example of a light source according to a first modification of the second embodiment;

FIG. 15B is a diagram illustrating an example of mixed-color light according to the first modification of the second embodiment;

FIG. 16A is a diagram illustrating an example of a light source according to a second modification of the second embodiment;

FIG. 16B is a diagram illustrating an example of mixed-color light according to the second modification of the second embodiment;

FIG. 17A is a diagram illustrating an example of a light sources according to a third modification of the second embodiment;

FIG. 17B is a diagram illustrating an example of mixed-color light according to the third modification of the second embodiment;

FIG. 18 is a cross-sectional view schematically illustrating an example of a light-emitting module according to a third embodiment;

FIG. 19 is a part of a chromaticity diagram of the CIE1931 color space, which illustrates a light-emitting region LSa of a first light-emitting part, a blackbody locus (having duv of 0), and loci having color deviations duv of −0.02, −0.01, 0.01, and 0.02 from the blackbody locus at correlated color temperatures;

FIG. 20 is a schematic diagram illustrating a first example of irradiation light from the light-emitting module according to the third embodiment; and

FIG. 21 is a schematic diagram illustrating a second example of irradiation light from the light-emitting module according to the third embodiment.

### DETAILED DESCRIPTION

Light-emitting modules according to embodiments of the present disclosure will be described in detail with reference to the accompanying drawings. The embodiments described below exemplify the light-emitting modules to embody the technical ideas of the present disclosure, but the present invention is not limited to the embodiments described below. In addition, unless otherwise specified, the dimensions, materials, shapes, relative arrangements, and the like of components described in the embodiments are not intended to limit the scope of the present disclosure thereto, but rather are described as examples. The sizes, positional relationships, and the like of members illustrated in the drawings may be exaggerated for a better understanding of the structures. Further, in the following description, the same names and reference numerals denote the same or similar members, and a detailed description thereof will be omitted as appropriate. An end view illustrating only a cut surface may be used as a cross-sectional view.

In the drawings, directions may be indicated by an X-axis, a Y-axis, and a Z-axis. An X-direction along the X-axis indicates a direction in which an object is moved by an actuator included in each of the light-emitting modules according to the embodiments, a Y-direction along the Y-axis indicates a direction orthogonal to the X-direction, and a Z-direction along the Z-axis indicates a direction orthogonal to both the X-direction and the Y-direction. The X direction is an example of a first direction. The Y direction is an example of a second direction intersecting the first direction.

Further, a direction indicated by an arrow in the X direction is referred to as a +X direction or a +X side, and a direction opposite to the +X direction is referred to as a −X direction or a −X side. A direction indicated by an arrow in the Y direction is referred to as a +Y direction or a +Y side, and a direction opposite to the +Y direction is referred to as a −Y direction or a −Y side. A direction indicated by an arrow in the Z direction is referred to as a +Z direction or a +Z side, and a direction opposite to the +Z direction is referred to as a −Z direction or a −Z side. In the embodiments, a surface of an object when viewed from the +Z direction or the +Z side is referred to as an “upper surface” and a surface of the object when viewed from the −Z direction or the −Z side is referred to as a “lower surface.”

In the embodiments, as an example, a plurality of light-emitting parts included in each of the light-emitting modules are configured to emit light toward the +Z side. In the drawings, light having different chromaticities, among the light emitted from the light-emitting parts, may be indicated by different types of arrows such as solid arrows or dashed arrows for description. The light-emitting module is configured such that a light source and a lens move relative to each other along the X direction or along both the X direction and the Y direction. The expression “in a top view” in the embodiments described below refers to viewing an object from the +Z side. However, these expressions do not limit the orientations of the light-emitting module during use, and the light-emitting module can be oriented in any appropriate direction during use. Further, light-emitting surfaces of the plurality of light-emitting parts are substantially parallel to the X-axis, and the optical axes of the plurality of light-emitting parts are along the Z-axis. In the present specification, each of the phrases “along the X-axis,” “along the Y-axis,” and “along the Z-axis” includes a case where an object is at an inclination within a range of ±10° with respect to the corresponding one of the axes.

The light-emitting modules according to the embodiments are each used as, for example, a flash light source of an imaging device. The light-emitting modules according to the embodiments enable photographing under irradiation light having a predetermined color by emitting light having a color adjusted to a predetermined color within an exposure period (a shutter open period) of the imaging device in which the light-emitting module is mounted. As used herein, the term “color adjustment” refers to adjusting the color of light. In the embodiments, the color of light is adjusted by mixing a plurality of lights having different chromaticities. In the present disclosure, the term “color mixing” means that lights having monochromatic wavelengths are mixed, lights having continuous spectra are mixed, and lights having a monochromatic wavelength and light having a continuous spectrum are mixed. The term “mixed-color light” refers to light obtained by such color mixing. In a case where the light-emitting modules according to the embodiments are each used as, for example, a flash light source of the imaging device, it is assumed that a plurality of lights having different chromaticities are integrated and mixed on an image sensor.

A configuration and functions of a light-emitting module will be described below in detail by illustrating, as an example, a light-emitting module mounted in a smartphone and used as a flash light source of an imaging device provided in the smartphone. Examples of the imaging device include a camera configured to capture a still image and a video camera for configured to capture a video. In the embodiments described below, an exposure period of the imaging device is an example of a predetermined period of time, but an imaging cycle of the imaging device may be set as the predetermined period of time.

### First Embodiment

### Example Configuration of Light-Emitting Module 100

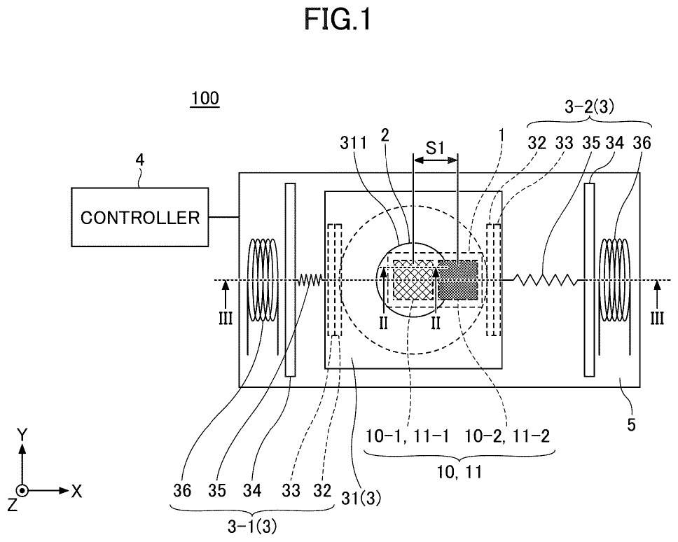

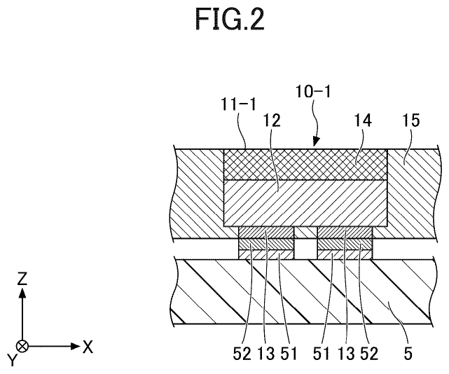

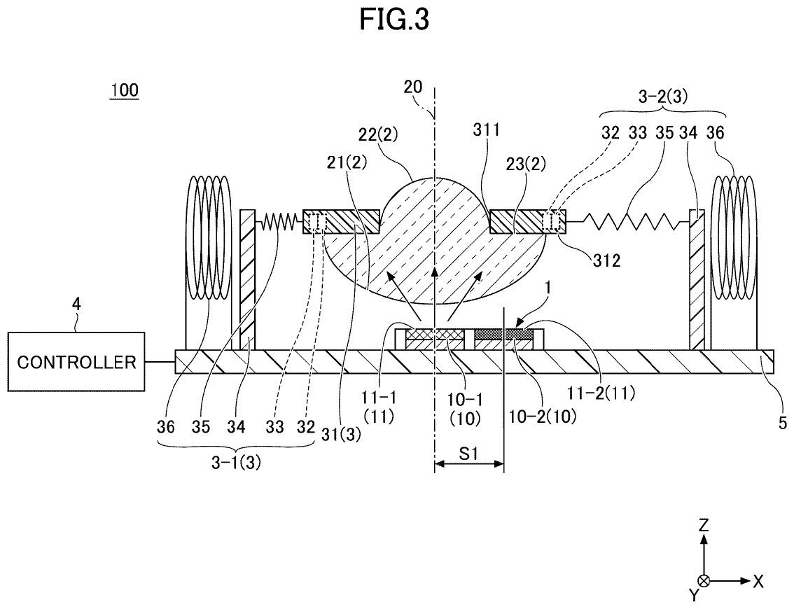

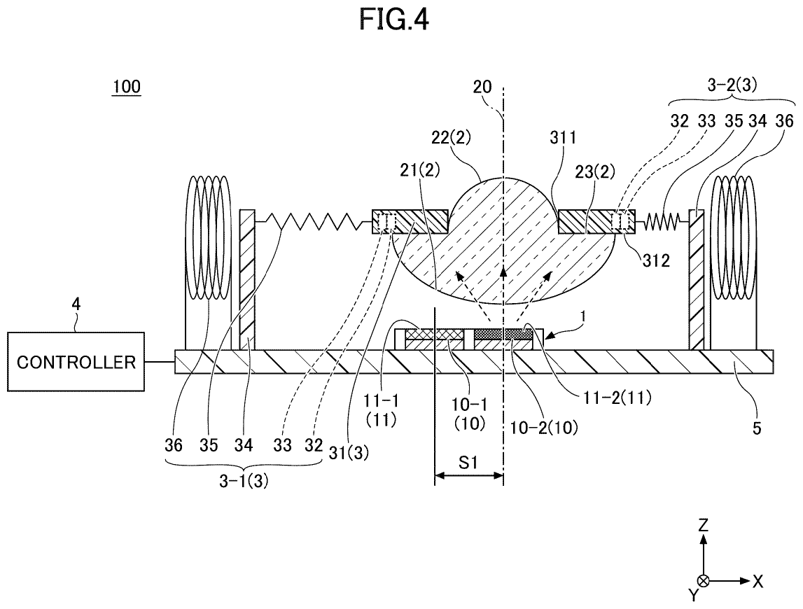

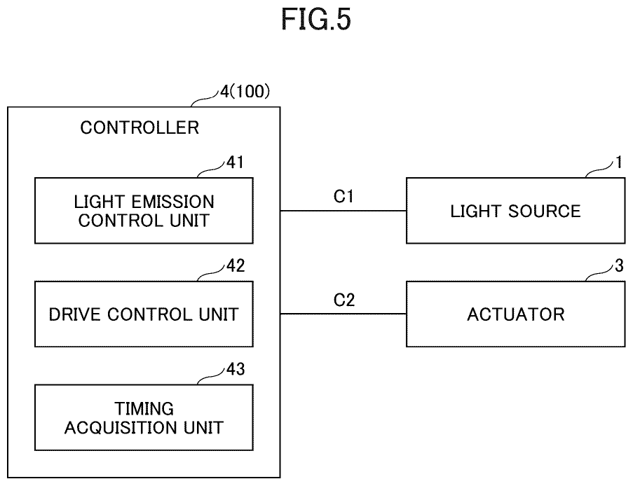

A light-emitting module 100 according to a first embodiment will be described with reference to FIG. 1 to FIG. 5. FIG. 1 is a top view illustrating an example of a configuration of the light-emitting module 100. FIG. 2 is a cross-sectional view taken along line II-II of FIG. 1. FIG. 3 is a cross-sectional view taken along line III-III of FIG. 1. FIG. 4 is a cross-sectional view illustrating an example of the light-emitting module after a lens 2 is moved in the +X direction from the state of FIG. 3. FIG. 5 is a block diagram illustrating an example of a functional configuration of a controller 4 of the light-emitting module 100.

As illustrated in FIG. 1 and FIG. 3, the light-emitting module 100 includes a light source 1, the lens 2, an actuator 3, and the controller 4.

In addition to the above components, the light-emitting module 100 can further include a housing that houses the light source 1, the lens 2, and the actuator 3 therein, a transparent part that is held in a state of being fitted into an opening formed in the housing, and the like. The transparent part is a member that protects the lens 2 and is disposed so as to overlap with the lens 2 in a top view. The transparent part preferably has a light transmittance of 80% or more with respect to light from the light source 1.

### (Light Source 1)

The light source 1 includes a plurality of light-emitting parts 10 including at least one first light-emitting part 10-1 configured to emit light having a first chromaticity and at least one second light-emitting part 10-2 configured to emit light having a second chromaticity different from the first chromaticity. In the light source 1, light is emitted from each of the plurality of light-emitting parts 10 toward the lens 2 located on the +Z side of the light source 1. The light source 1 includes at least one first light-emitting part 10-1. Further, the light source 1 includes at least one second light-emitting part 10-2. The number of first light-emitting parts 10-1 and the number of second light-emitting parts 10-2 can be changed as appropriate according to the application or the like of light-emitting module 100.

The plurality of light-emitting parts 10 have respective light-emitting surfaces 11. The first light-emitting part 10-1 has a first light-emitting surface 11-1. The second light-emitting part 10-2 has a second light-emitting surface 11-2. The light-emitting surfaces 11 refer to main light extraction surfaces of the respective light-emitting parts 10.

Each of the first light-emitting part 10-1 and the second light-emitting part 10-2 each have a substantially rectangular shape in a top view. The first light-emitting part 10-1 and the second light-emitting part 10-2 are mounted on the surface on the +Z side (in other words, the upper surface) of a light-emitting-part mounting substrate 5. The length of each of the first light-emitting part 10-1 and the second light-emitting part 10-2 in the X direction or the Y direction, in other words, the length of one side of each of the first light-emitting part 10-1 and the second light-emitting part 10-2 is, for example, 200 μm or more and 2,000 μm or less and preferably 500 μm or more and 1,500 μm or less.

The first light-emitting part 10-1 and the second light-emitting part 10-2 include respective light-emitting diodes (LEDs). Light emitted from each of the first light-emitting part 10-1 and the second light-emitting part 10-2 is preferably white light, but can be monochromatic light. The color of the light emitted from each of the first light-emitting part 10-1 and the second light-emitting part 10-2 can be appropriately selected according to the application of the light-emitting module 100. The first light-emitting part 10-1 and the second light-emitting part 10-2 can include laser diodes (LDs).

In FIG. 1, the light-emitting parts 10 overlap with the light-emitting surfaces 11 in a top view, and thus the reference numerals of the light-emitting part 10 are illustrated together with the reference numerals of the light-emitting surfaces 11. Further, the first light-emitting part 10-1 overlaps with the first light-emitting surface 11-1 in a top view, and thus the reference numeral of the first light-emitting part 10-1 is illustrated together with the reference numeral of the first light-emitting surface 11-1. The second light-emitting part 10-2 overlaps with the second light-emitting surface 11-2 in a top view, and thus the reference numeral of the second light-emitting part 10-2 is illustrated together with the reference numeral of the second light-emitting surface 11-2. Hereinafter, in a case where two or more components substantially coincide with one another or overlap with one another, the reference numerals may be illustrated together.

The first light-emitting part 10-1 and the second light-emitting part 10-2 are preferably disposed inward of the lens 2 (inward relative to the contour of the lens 2) in a top view. From the viewpoint of light emission characteristics of the light-emitting module 100, the narrower a distance S1 between the centers of adjacent light-emitting parts of the plurality of light-emitting parts 10, the more preferable. The distance S1 between the centers of the adjacent light-emitting parts of the plurality of light-emitting parts 10 is preferably 210 μm or more and 2,200 μm or less and more preferably 550 μm or more and 1,700 μm or less. However, there are limits to the intervals at which the plurality of light-emitting parts 10 are mounted can be made. In order to obtain good light emission characteristics while providing narrow intervals at which the plurality of light-emitting parts 10 can be mounted, the distance between light-emitting surfaces 11 of the adjacent light-emitting parts of the plurality of light-emitting parts 10 is preferably 10 μm or more and 200 μm or less and more preferably 20 μm or more and 50 μm or less.

As illustrated in FIG. 2, the first light-emitting part 10-1 is mounted on the surface on the +Z side of the light-emitting-part mounting substrate 5, with a surface on the +Z side of the first light-emitting part 10-1 serving as the first light-emitting surface 11-1 and a surface opposite to the first light-emitting surface 11-1 serving as a mounting surface. The first light-emitting part 10-1 includes a light-emitting element 12, a light-transmissive member 14 provided on the surface on the +Z side of the light-emitting element 12, and a covering member 15 covering the lateral surfaces of the light-emitting element 12 and the lateral surfaces of the light-transmissive member 14 without covering the upper surface (on the +Z side) of the light-transmissive member 14.

At least a pair of positive and negative electrodes 13 (for example, a p-side electrode and an n-side electrode) are preferably provided on the surface of the light-emitting element 12 opposite to the first light-emitting surface 11-1. In the present embodiment, the outer shape of the first light-emitting surface 11-1 in a top view is a substantially rectangular shape. However, the outer shape of the first light-emitting surface 11-1 in a top view can be a substantially circular shape or a substantially elliptical shape, or can be a polygonal shape such as a substantially triangular shape or a substantially hexagonal shape.

The light-emitting element 12 is preferably formed of various semiconductors such as group III-V compound semiconductors and group II-VI compound semiconductors. The light-emitting element 12 can be a LED or can be a LD. As the semiconductors, nitride-based semiconductors such as InₓAl_{Y}Ga_{1-X-Y}N (0≤X, 0≤Y, X+Y≤1) are preferably used, and InN, AlN, GaN, InGaN, AlGaN, InGaAlN, and the like can also be used. The peak emission wavelength of the light-emitting element 12 is preferably 400 nm or more and 530 nm or less, more preferably 400 nm or more and 490 nm or less, and even more preferably 440 nm or more and 475 nm or less, from the viewpoint of light emission efficiency, excitation of a wavelength conversion substance, a color mixing relationship with the light emission thereof, and the like.

The light-transmissive member 14 is a member having, for example, a substantially rectangular shape in a top view, and is disposed so as to cover the upper surface of the light-emitting element 12. The light-transmissive member 14 can be formed using a light-transmissive resin material or an inorganic material such as a ceramic or glass. As the resin material, a thermosetting resin such as a silicone resin, a silicone-modified resin, an epoxy resin, an epoxy-modified resin, or a phenol resin can be used. In particular, a silicone resin or a modified resin thereof having high light resistance and heat resistance is preferable. As used herein, “light-transmissive” means that 60% or more of light from the light-emitting element 12 is preferably transmitted. Further, a thermoplastic resin such as a polycarbonate resin, an acrylic resin, a methylpentene resin, or a polynorbornene resin can be used for the light-transmissive member 14. Further, the light-transmissive member 14 can contain a light diffusing substance or a wavelength conversion substance that converts the wavelength of at least a portion of the light from the light-emitting element 12. For example, the light-transmissive member 14 can be a resin material, a ceramic, glass, or the like containing a wavelength conversion substance, a sintered body of a wavelength conversion substance, or the like. Further, the light-transmissive member 14 can be a multilayer member in which a resin layer containing a wavelength conversion substance or a light diffusing substance is disposed on the surface on the ±Z side of a formed body of a resin, a ceramic, glass, or the like.

Examples of a wavelength conversion substance contained in the light-transmissive member 14 include yttrium aluminum garnet based phosphors (for example, (Y,Gd)₃(Al,Ga)₅O₁₂:Ce), lutetium aluminum garnet based phosphors (for example, Lu₃(Al,Ga)₅O₁₂:Ce), terbium aluminum garnet based phosphors (for example, Tb₃(Al,Ga)₅O₁₂:Ce), CCA based phosphors (for example, Ca₁₀(PO₄)₆Cl₂:Eu), SAE based phosphors (for example, Sr₄Al₁₄O₂₅:Eu), chlorosilicate based phosphors (for example, Ca₈MgSi₄O₁₆Cl₂:Eu), silicate based phosphors (for example, (Ba,Sr,Ca,Mg):₂SiO₄:Eu), oxynitride based phosphors such as β-SiAlON based phosphors (for example, (Si,Al)₃(O,N)₄:Eu) and α-SiAlON based phosphors (for example, Ca(Si,Al)₁₂(O,N)₁₆:Eu), nitride based phosphors such as LSN based phosphors (for example, (La,Y)₃Si₆N₁₁:Ce), BSESN based phosphors (for example, (Ba,Sr)₂Si₅N₈:Eu), SLA based phosphors (for example, SrLiAl₃N₄:Eu), CASN based phosphors (for example, CaAlSiN₃:Eu), and SCASN based phosphors (for example, (Sr,Ca)AlSiN₃:Eu), fluoride based phosphors such as KSF based phosphors (for example, K₂SiF₆:Mn), KSAF based phosphors (for example, K₂(Si₁₋ₓAlₓ) F₆₋ₓ:Mn, where x satisfies 0<x<1), and MGF based phosphors (for example, 3.5 MgO·0.5 MgF₂·GeO₂:Mn), quantum dots having a Perovskite structure (for example, (Cs,FA,MA) (Pb,Sn) (F,Cl,Br,I)₃, where FA and MA represent formamidinium and methylammonium, respectively), II-VI quantum dots (for example, CdSe), III-V quantum dots (for example, InP), and quantum dots having a chalcopyrite structure (for example, (Ag,Cu) (In,Ga) (S,Se)₂). The phosphors above are particles. One of these wavelength conversion substances can be used alone, or two or more of these wavelength conversion substances can be used in combination.

In the present embodiment, in the first light-emitting part 10-1, a blue light emitting element is used as the light-emitting element 12. A wavelength conversion substance contained in the light-transmissive member 14 coverts the wavelength of a portion of blue light emitted from the light-emitting element 12 into the wavelength of yellow light, and the blue light and the yellow light are mixed (that is, the colors are mixed). Accordingly, white light can be emitted. The white light emitted from the first light-emitting part 10-1 is an example of light having a first chromaticity. As the light-diffusing substance contained in the light-transmissive member 14, for example, titanium oxide, barium titanate, aluminum oxide, silicon oxide, or the like can be used.

The covering member 15 is a member covering the lateral surfaces of the light-emitting element 12 and the lateral surfaces of the light-transmissive member 14. The covering member 15 directly or indirectly covers the lateral surfaces of the light-emitting element 12 and the lateral surfaces of the light-transmissive member 14. The upper surface of the light-transmissive member 14 is not covered by the covering member 15, and is the light-emitting surface 11-1 of the light-emitting part 10-1. The covering member 15 can be separated between adjacent light-emitting parts of the plurality of light-emitting parts 10. In order to improve the light extraction efficiency, the covering member 15 is preferably formed of a member having a high light reflectance. For example, a resin material containing a light reflective substance such as a white pigment can be used for the covering member 15.

Examples of the light reflective substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like. It is preferable to use one of the above substances alone or a combination of two or more of the above substances. Further, for the resin material, it is preferable to use a base material including a resin material whose main component is a thermosetting resin such as an epoxy resin, an epoxy-modified resin, a silicone resin, a silicone-modified resin, or a phenol resin. The covering member 15 can be composed of a member having light reflectivity with respect to visible light as necessary.

The light-emitting-part mounting substrate 5 is a plate-shaped member having a substantially rectangular shape in a top view. The light-emitting-part mounting substrate 5 is a substrate that includes conductive members and on which light-emitting elements and various electrical elements can be mounted. The light-emitting-part mounting substrate 5 preferably includes conductive members 51 each disposed on at least one of a surface or the inside thereof. The light-emitting-part mounting substrate 5 and each of the light-emitting parts 10 are electrically connected to each other by connecting the conductive members 51 of the light-emitting-part mounting substrate 5 to at least a pair of positive and negative electrodes 13 of each of the light-emitting parts 10 via electrically-conductive adhesive members 52. The configuration, the size, and the like of the conductive members 51 of the light-emitting-part mounting substrate 5 are set according to the configuration, the size, and the like of the electrodes 13 of each of the light-emitting parts 10.

As a base material, the light-emitting-part mounting substrate 5 preferably uses an insulating material, preferably uses a material through which light emitted from the light-emitting parts 10, external light, or the like is not easily transmitted, and preferably uses a material having a certain strength. Specifically, as a base material of the light-emitting-part mounting substrate 5, a ceramic such as alumina, aluminum nitride, mullite, or silicon nitride, or a resin such as a phenol resin, an epoxy resin, a polyimide resin, a bismaleimide-triazine resin (BT resin), polyphthalamide, or a polyester resin can be used.

The conductive members 51 can be composed of at least one selected from the group consisting of, for example, copper, iron, nickel, tungsten, chromium, aluminum, silver, gold, titanium, palladium, rhodium, and alloys thereof. In addition, a layer of silver, platinum, aluminum, rhodium, gold, an alloy thereof, or the like can be provided on the surface layer of the conductive members 51 from the viewpoint of wettability and/or light reflectivity of the electrically-conductive adhesive members 52.

The configuration of the second light-emitting part 10-2 can be substantially the same as the configuration of the first light-emitting part 10-1 illustrated in FIG. 2, as long as the chromaticity (second chromaticity) of the light emitted from the second light-emitting part 10-2 is different from the chromaticity (first chromaticity) of the light emitted from the first light-emitting part 10-1. For example, the configuration of the second light-emitting part 10-2 can be the same as the configuration of the first light-emitting part 10-1 in FIG. 2 except for the configuration of the light-transmissive member. The second light-emitting part 10-2 includes a light-transmissive member, having a configuration at least partially different from that of the light-transmissive member 14 of the first light-emitting part 10-1, at a position where the light-transmissive member 14 is located in FIG. 2. The light-transmissive member included in the second light-emitting part 10-2 of the present embodiment contains a wavelength conversion substance that converts the wavelength of light emitted from a corresponding light-emitting element 12. As an example, the second light-emitting part 10-2 can emit the light having the second chromaticity, which is obtained by mixing light emitted from the light-emitting element 12 and light converted by the wavelength conversion substance contained in the light-transmissive member of the second light-emitting part 10-2.

As long as the chromaticity (second chromaticity) of the light emitted from the second light-emitting part 10-2 is different from the chromaticity (first chromaticity) of the light emitted from the first light-emitting part 10-1, a material the same as or similar to the material of the light-transmissive member 14 of the first light-emitting part 10-1 as described above can be used for the light-transmissive member of the second light-emitting part 10-2. The light-transmissive member of the second light-emitting part 10-2 can be a member in which a wavelength conversion substance is contained in, for example, a resin, glass, a ceramic, or the like that serves as a base material, can be a member in which a wavelength conversion substance is printed on the surface of a formed body such as glass, or can be a sintered body of a wavelength conversion substance. In the light-transmissive member of the second light-emitting part 10-2, as a wavelength conversion substance, one of the wavelength conversion substances described above as the examples of the wavelength conversion substance of the light-transmissive member 14 alone can be used, or two or more of these wavelength conversion substances in combination can be used.

### (Lens 2)

In FIG. 3, the lens 2 is configured to transmit light from the light source 1. The light transmitted through the lens 2 is irradiated on an irradiation region located on the +Z side of the light-emitting module 100. The lens 2 according to the present embodiment is a biconvex single lens. The lens 2 includes a first convex surface 21 that protrudes in a direction in which the light source 1 is located (toward the −Z side), a second convex surface 22 that protrudes in a direction opposite to the direction in which the light source 1 is located (toward the +Z side), and a flat surface portion 23 that is an annular portion formed around the second convex surface 22. An optical axis 20 is an optical axis of the lens 2. The optical axis 20 can also be referred to as a central axis of the lens 2. The radius of curvature of the first convex surface 21 is larger than the radius of curvature of the second convex surface 22. Accordingly, light from the light-emitting parts 10 can be efficiently incident on the lens 2. The outer shape of the lens 2 is a substantially circular shape in a top view. By using a biconvex lens in which both an incident surface and an exit surface of the light from the light source 1 are convex surfaces, it is possible to improve the degree of freedom of control of the light transmitted through the lens 2, as compared to when a lens in which either the incident surface or the exit surface is a flat surface is used as the lens 2.

The lens 2 is not limited the biconvex single lens, and can be a concave lens or a meniscus lens, or can be a combined lens including a plurality of lenses. The radius of curvature of each of the first convex surface 21 and the second convex surface 22, the thickness of the lens 2, and the like can be adjusted as appropriate. Further, the outer shape of the lens 2 in a top view is not limited to the substantially circular shape, and can be a substantially polygonal shape, such as a substantially triangular shape or a substantially rectangular shape, or a substantially elliptical shape. Each of the plurality of light-emitting surfaces 11 is preferably located inward of the lens 2 (inward relative to the contour of the lens 2) in a top view.

The lens 2 includes at least one of: a resin material, such as a polycarbonate resin, an acrylic resin, a silicone resin, or an epoxy resin; or a glass material. As used herein, “light transmissive” refers to a property that allows 60% or more of the light from each of the light-emitting parts 10 to be transmitted.

### (Actuator 3)

The actuator 3 changes the relative position between the light source 1 and the lens 2 in a direction intersecting the optical axis 20 of the lens 2. As illustrated in FIG. 1, FIG. 3, and FIG. 4, the actuator 3 includes an electromagnetic actuator configured to change the relative position between the light source 1 and the lens 2 by causing a relative movement of the lens 2 with respect to the light source 1 in the X direction. The actuator 3 is provided on the surface on the +Z side of the light-emitting-part mounting substrate 5. The X direction is a direction substantially parallel to the light-emitting surfaces 11 and substantially parallel to the surface on the +Z side of the light-emitting-part mounting substrate 5. The direction intersecting the optical axis 20 of the lens 2 is preferably a direction orthogonal to the optical axis 20 of the lens 2. As used herein, the direction orthogonal to the optical axis 20 of the lens 2 includes a case where the direction is inclined within a range of ±10° with respect to the optical axis 20 of the lens 2, and, in the present embodiment, is a direction along the light-emitting surfaces 11 of the light source 1.

The actuator 3 includes a frame 31, a first actuator 3-1, and a second actuator 3-2. Each of the first actuator 3-1 and the second actuator 3-2 includes an N-pole magnet 32, an S-pole magnet 33, a support 34, a spring 35, and a coil 36.

The N-pole magnet 32, the S-pole magnet 33, the support 34, the spring 35, and the coil 36 included in the first actuator 3-1 are arranged on the −X side of the lens 2. The N-pole magnet 32, the S-pole magnet 33, the support 34, the spring 35, and the coil 36 included in the second actuator 3-2 are arranged on the +X side of the lens 2.

The frame 31 supports the lens 2. The two supports 34 are fixed onto the surface on the +Z side of the light-emitting-part mounting substrate 5. The two supports 34 support the frame 31 from both sides of the frame 31 in the X direction via the springs 35. The two N-pole magnets 32 and the two S-pole magnets 33 are fixed inside the frame 31. The S-pole magnets 33 are located outward of the N-pole magnets 32 within the frame 31. Each of the two coils 36 faces a respective S-pole magnet 33 with the support 34 and the spring 35 located between the respective coil 36 and the respective S-pole magnet 33. The actuator 3 moves the frame 31 in the −X direction or the +X direction by an electromagnetic force generated by a current flowing through each of the two coils 36.

As illustrated in FIG. 3, in the case of moving the frame 31 in the −X direction, the first actuator 3-1 moves the frame 31 closer to the coil 36 and the second actuator 3-2 moves the frame 31 further away from the coil 36. As illustrated in FIG. 4, in the case of moving the frame 31 in the +X direction, the first actuator 3-1 moves the frame 31 further away from the coil 36 and the second actuator 3-2 moves the frame 31 closer to the coil 36. The actuator 3 changes the relative position of the lens 2 with respect to the light source 1 fixed to the light-emitting-part mounting substrate 5 by moving the frame 31.

The frame 31 is a member having a substantially rectangular outer shape in a top view and having a substantially circular opening 311 on the inner side thereof. The lens 2 is disposed such that the second convex surface 22 passes through the opening 311, and the flat surface portion 23 of the lens 2 and a lower surface 312 of the frame 31 are bonded together with an adhesive member or the like.

In this manner, the frame 31 supports the lens 2. The lower surface 312 of the frame 31 is a surface facing the light-emitting-part mounting substrate 5. The frame 31 includes a resin material, a metal material, or the like. The frame 31 preferably includes, at a surface or the inside thereof, a color material such as a black material that can absorb light emitted from the light-emitting parts 10. With this configuration, light that has leaked to the frame 31 side through the lens 2 can be absorbed by the frame 31, and thus light reflected by the frame 31 can be inhibited from returning to the lens 2 side.

The N-pole magnets 32 and the S-pole magnets 33 are members including a metal material or the like. Each of the N-pole magnets 32 and the S-pole magnet 33 can have any appropriate shape, and in the present embodiment, has a quadrangular columnar shape. The N-pole magnets 32 are magnetized to be N N-pole magnets, and the S-pole magnets 33 are magnetized to be S-pole magnets. The number of the N-pole magnets 32 and the number of the S-pole magnets 33 can be any appropriate number. One of the two N-pole magnets 32 and one of the two S-pole magnets 33 are provided in the vicinity of a side on the −X side, of two sides extending along the Y direction, of the frame 31. The other N-pole magnet of the two N-pole magnets 32 and the other S-pole magnet of the two S-pole magnets 33 are provided in the vicinity of a side on the +X side, of the two sides extending along the Y direction, of the frame 31. The two N-pole magnets 32 and the two S-pole magnets 33 are not necessarily provided inside the frame 31, and can be fixed to an outer lateral surface of the frame 31 by an adhesive member or the like, or can be housed in a recess formed in the frame 31 and fixed by an adhesive member or the like.

The support 34 is preferably formed of a member having a light-shielding property and preferably includes a resin material or the like containing a filler such as a light reflective substance as described above or a light-absorbing substance such as carbon, such that the distribution direction of the light emitted from the light-emitting module 100 can be restricted.

The springs 35 are elastic members that are configured to expand and contract in the X direction. Any appropriate material can be used as a material of the springs 35, and a metal material, a resin material, or the like can be used as a material of the springs 35. The number of the springs 35 can be any appropriate number. One end of each of the two springs 35 is connected to the frame 31, and the other end of each of the springs 35 is connected to a corresponding one of the supports 34. The springs 35 limit excessive movement of the frame 31, and impart a restoring force to the frame 31 that causes the frame 31 to return to its initial position.

The coils 36 are members that can conduct a current. The coils 36 are each formed by winding a wire or the like into a spiral shape or a coil shape. Each of the two coils 36 is paired with a pair of one N-pole magnet 32 and one S-pole magnet 33. The two coil 36 are fixed onto the surface on the +Z side of the light-emitting-part mounting substrate 5. The number of the coils 36 is not limited to two, and can be any appropriate number in accordance with the number of the N-pole magnets 32 and the S-pole magnets 33.

In response to supply of a drive current from the controller 4 to each of the two coils 36, an electromagnetic force is generated according to the right-hand rule by the action of the two N-pole magnets 32, the two S-pole magnets 33, and the two coils 36. The frame 31 moves according to a direction in which the generated electromagnetic force acts on the frame 31. The magnitude of an electromagnetic force to be generated changes in accordance with the amount of the drive current flowing through each of the two coils 36, and thus the amount of movement of the lens 2 changes. Further, the direction of an electromagnetic force to be generated changes in accordance with the direction of the drive current flowing through each of the two coils 36, and thus the direction of movement of the lens 2 changes.

In the present embodiment, the actuator 3 causes the lens 2 to move in the X direction by a distance substantially equal to the distance S1 between the centers of the adjacent light-emitting parts of the plurality of light-emitting parts 10. Accordingly, the actuator 3 can switch between a state A in which the optical axis 20 of the lens 2 intersects the first light-emitting surface 11-1, that is, the state of FIG. 3, and a state B in which the optical axis 20 of the lens 2 intersects the second light-emitting surface 11-2, that is, the state of FIG. 4. The driving method of the actuator 3 is not limited to the electromagnetic method, and can be a piezoelectric method or an ultrasonic method.

### (Controller 4)

The controller 4 can control light emission of each of the plurality of light-emitting parts 10 of the light source 1 and the operation of the actuator 3. In the present embodiment, the controller 4 performs control such that, on the irradiation region, there is at least partial overlap between (i) a position on which light emitted from the first light-emitting part 10-1 and transmitted through the lens 2 is incident before a change in the relative position between the light source 1 and the lens 2 in a direction intersecting the optical axis 20 of the lens 2 and (ii) a position on which light emitted from the second light-emitting part 10-2 and transmitted through the lens 2 is incident after the change in the relative position.

The controller 4 is connected to the plurality of light-emitting parts 10 and the actuator 3 in a wired or wireless manner. The controller 4 can control light emission of each of the plurality of light-emitting parts 10 and the operation of the actuator 3 by outputting a control signal to each of the plurality of light-emitting parts 10 and the actuator 3 through the light-emitting-part mounting substrate 5. The controller 4 can be installed at any appropriate position.

In a case where the controller 4 is connected in a wireless manner, the controller 4 can be disposed away from the plurality of light-emitting parts 10 and the actuator 3.

As illustrated in FIG. 5, the controller 4 includes a light emission control unit 41, a drive control unit 42, and a timing acquisition unit 43. In addition to implementing functions of these units by an electrical circuit, the controller 4 can also implement some or all of the functions by a central processing unit (CPU). The controller 4 can implement the functions by a plurality of circuits or a plurality of processors.

The light emission control unit 41 controls light emission of each of the plurality of light-emitting parts 10. Further, the light emission control unit 41 can selectively cause at least one of the plurality of light-emitting parts 10 to emit light.

In addition, the light emission control unit 41 can individually control the amount of light emitted from each of the plurality of light-emitting parts 10 by controlling at least one of a drive current, a drive voltage, or a light emission period of time of each of the plurality of light-emitting parts 10. In the present embodiment, the light emission control unit 41 controls the drive current of each of the plurality of light-emitting parts 10 by outputting a first control signal C1, thereby controlling light emission of each of the plurality of light-emitting parts 10.

The drive control unit 42 controls the operation of the actuator 3. For example, the drive control unit 42 controls a drive current to be applied to the two coils 36 and the direction of the drive current by outputting a second control signal C2, thereby controlling the operation of the actuator 3.

In the present embodiment, the actuator 3 performs control such that the lens 2 is brought into both the state A and the state B within the exposure period of the imaging device in which the light-emitting module 100 is mounted. The state A corresponds to a state before the relative position between the light source 1 and the lens 2 in a direction intersecting the optical axis 20 of the lens 2 is changed. The state B corresponds to a state after the relative position between the light source 1 and the lens 2 in a direction intersecting the optical axis 20 of the lens 2 is changed. By performing control such that the lens 2 is brought into both the state A and the state B within the exposure period of the imaging device, the controller 4 can cause a position on which light emitted from the first light-emitting part 10-1 and transmitted through the lens 2 is incident in the state A to overlap with a position on which light emitted from the second light-emitting part 10-2 and transmitted through the lens 2 is incident in the state B.

The timing acquisition unit 43 acquires timing information, such as a signal indicating start or end of the exposure period of the imaging device, from the smartphone. The light emission control unit 41 and the drive control unit 42 can perform control according to the timing information acquired by the timing acquisition unit 43.

### Example Operation of Light-Emitting Module 100

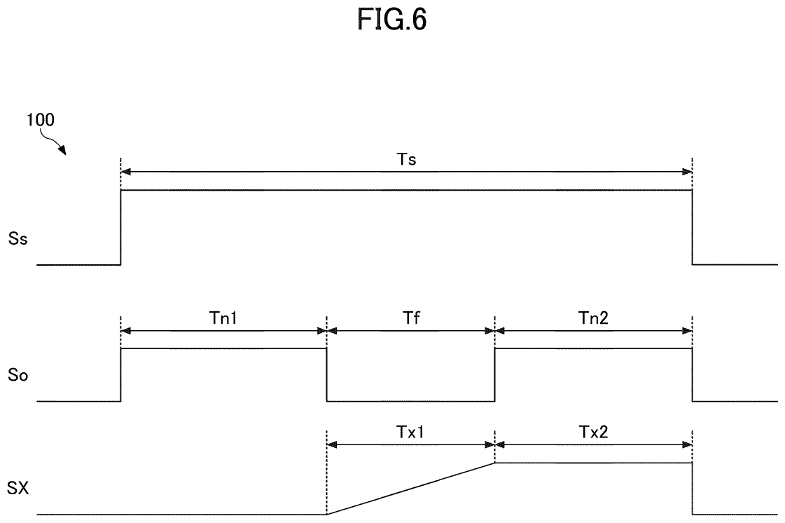

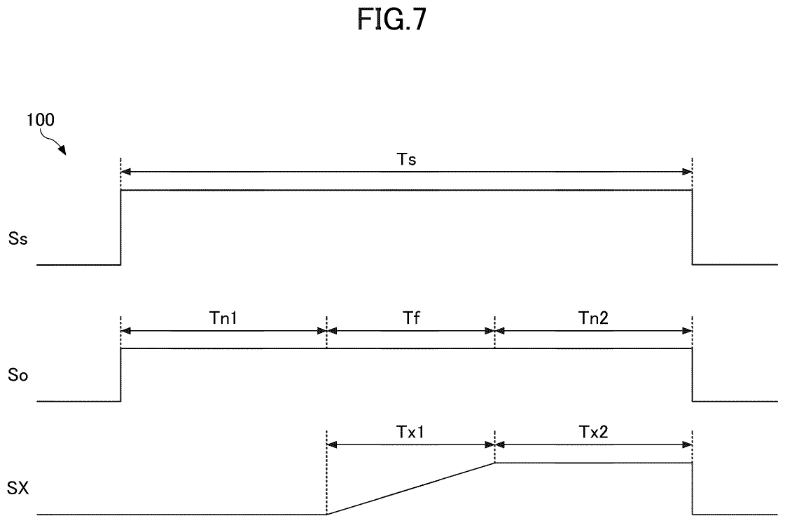

Next, the operation of the light-emitting module 100 will be described with reference to FIG. 6 and FIG. 7. FIG. 6 and FIG. 7 are timing charts illustrating examples of the operation of the light-emitting module 100. FIG. 6 illustrates a first example, and FIG. 7 illustrates a second example.

Each of FIG. 6 and FIG. 7 shows an exposure signal Ss, a light emission signal So, and an X position signal SX. The exposure signal Ss indicates an exposure timing of the imaging device in which the light-emitting module 100 is mounted. The light emission signal So indicates a light emission timing of each of the plurality of light-emitting parts 10 of the light-emitting module 100. The X position signal SX indicates the position of the lens 2 in the X direction. The vertical axis of the light emission signal So in each of FIG. 6 and FIG. 7 is a current value. In the examples of FIG. 6 and FIG. 7, it is assumed that the plurality of light-emitting parts 10 operates independently from each other. However, the plurality of light-emitting parts 10 can perform the same operation.

An exposure period Ts is a period of time during which a shutter of the imaging device is opened. The exposure period Ts is, for example, 1/60 second or more and 1 second or less. The shutter is opened at a time when the exposure signal Ss is in an on state, and the shutter is closed at a time when the exposure signal Ss is in an off state.

A first light emission period Tn1 is a period of time (in other words, a duration of time) during which the first light-emitting part 10-1 emits light (in other words, is turned on) and the second light-emitting part 10-2 does not emit light (in other words, is turned off). A second light emission period Tn2 is a period of time during which the second light-emitting part 10-2 emits light and the first light-emitting part 10-1 does not emit light. A non-light emission period Tf is a period of time during which both the first light-emitting part 10-1 and the second light-emitting part 10-2 do not emit light. At a time when the light emission signal So is switched from an off state to an on state, the first light-emitting part 10-1 or the second light-emitting part 10-2 emits light. At a time when the light emission signal So is switched from the on state to the off state, both the first light-emitting part 10-1 and the second light-emitting part 10-2 are caused not to emit light.

A movement period Tx1 is a period of time during which the lens 2 is moved along the X direction by the actuator 3. In the movement period Tx1, the X position signal SX is changed with time. In a stopping period Tx2, the X position signal SX is constant, and the lens 2 is stopped. The movement in the movement period Tx1 corresponds to the movement of the lens 2 from the position in the state A to the position in the state B.

When the exposure period Ts is started in response to the timing acquisition unit 43 illustrated in FIG. 5 acquiring timing information from the smartphone, first, in the first light emission period Tn1, the light emission control unit 41 illustrated in FIG. 5 of the light-emitting module 100 causes the first light-emitting part 10-1 to emit light and causes the second light-emitting part 10-2 not to emit light. In the first light emission period Tn1, the first lens 2 is in the state A (see FIG. 3) in which the optical axis 20 of the lens 2 intersects the first light-emitting surface 11-1. In the first light emission period Tn1, the lens 2 is stopped.

Subsequently, in the movement period Tx1, the drive control unit 42 of the light-emitting module 100 causes the lens 2 to move in the +X direction by a distance substantially equal to the distance S1 between the centers of the adjacent light-emitting parts. Further, in the non-light emission period Tf parallel to the movement period Tx1, the light emission control unit 41 of the light-emitting module 100 causes the plurality of light-emitting parts 10 not to emit light. That is, the light emission control unit 41 causes the plurality of light-emitting parts 10 not to emit light while the relative position between the light source 1 and the lens 2 is changed by the actuator 3. The lens 2 stops after moving in the +X direction by the distance substantially equal to the distance S1 between the centers of the adjacent light-emitting parts. The movement period Tx1 corresponds to a period of time during which “the relative position between the light source 1 and the lens 2 is changed by the actuator 3.”

Subsequently, in the second light emission period Tn2, the light emission control unit 41 of the light-emitting module 100 causes the second light-emitting part 10-2 to emit light and causes the first light-emitting part 10-1 not to emit light. In the second light emission period Tn2, the lens 2 is in the state B (see FIG. 4) in which the optical axis 20 of the lens 2 intersects the second light-emitting surface 11-2. In the second light emission period Tn2, the lens 2 is stopped.

As described above, the light-emitting module 100 can switch between the state A and the state B within the exposure period Ts.

In the second example illustrated in FIG. 7, the light emission signal So continues to be in the on state even in the movement period Tx1, and the plurality of light-emitting parts 10 continue to emit light instead of being totally turned off. In this case, in the movement period Tx1, either the first light-emitting part 10-1 or the second light-emitting part 10-2 can emit light, or both the first light-emitting part 10-1 and the second light-emitting part 10-2 can emit light. That is, the light emission control unit 41 can cause the plurality of light-emitting parts 10 to emit light in the movement period Tx1.

### Examples of Irradiation Light from Light-Emitting Module 100

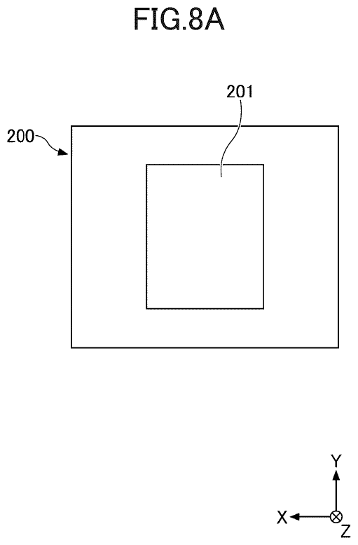

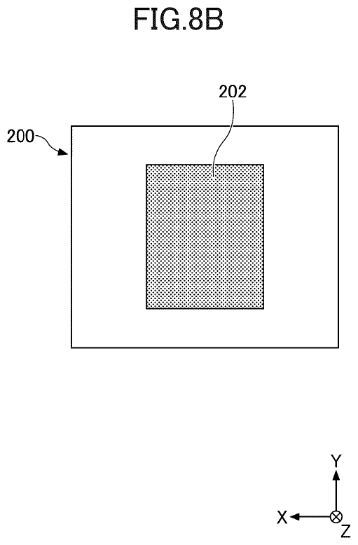

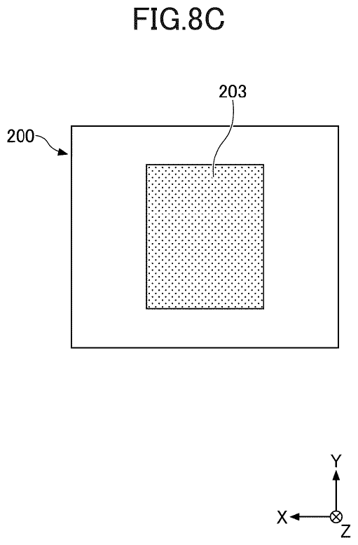

FIG. 8A, FIG. 8B, and FIG. 8C are diagrams illustrating examples of irradiation light from the light-emitting module 100 illustrated in FIG. 1. FIG. 8A is a diagram illustrating an example of irradiation light in the state A illustrated in FIG. 3.

FIG. 8B is a diagram illustrating an example of irradiation light in the state B illustrated in FIG. 4.

FIG. 8C is a diagram illustrating an example of mixed-color light obtained by mixing the irradiation light of FIG. 8A and the irradiation light of FIG. 8B. The mixed-color light in the present embodiment refers to light in which light having the first chromaticity and light having the second chromaticity are mixed. FIG. 8A, FIG. 8B, and FIG. 8C illustrate the irradiation light when an irradiation region 200 is viewed in a direction in which the light-emitting module 100 is located. The irradiation region 200 is a region located on the +Z side of the light-emitting module 100 illustrated in FIG. 1, and is a region to be irradiated with light from the light-emitting module 100.

As illustrated in FIG. 8A, in the state A, light emitted from the first light-emitting part 10-1 is irradiated, as first irradiation light 201, on the irradiation region 200. The color of the first irradiation light 201 corresponds to the first chromaticity. The size of an area on which the first irradiation light 201 in incident in the irradiation region 200 is substantially equal to the size of the first light-emitting surface 11-1 multiplied by a magnification β. For example, the same is true if an image is completely formed by the lens 2. Conversely, if an image formed by the lens 2 is slightly blurred, that is, if an image is not completely formed so as to improve illuminance unevenness or the like, the size of the area on which the first irradiation light 201 is incident is slightly larger than the size of the first light-emitting surface 11-1 multiplied by the magnification β. For example, when the length of the first light-emitting surface 11-1 in the X direction is defined as dx and the length of the first light-emitting surface 11-1 in the Y direction is defined as dy, a length in the X direction of an area on which the first irradiation light 201 is incident in the irradiation region 200 is substantially equal to β×dx, and a length in the Y direction of the area is substantially equal to β×dy. The magnification β corresponds to the lateral magnification of the lens 2. The lateral magnification of the lens 2 refers to the magnification of the lens 2 in a direction orthogonal to the optical axis of the lens 2.

As illustrated in FIG. 8B, in the state B, light emitted from the second light-emitting part 10-2 is irradiated, as second irradiation light 202, onto the irradiation region 200. The color of the second irradiation light 202 corresponds to the second chromaticity. The size of an area on which the second irradiation light 202 is incident in the irradiation region 200 is substantially equal to the size of the second light-emitting surface 11-2 multiplied by the magnification β. Similar to the state A described above, if an image formed by the lens 2 is a slightly blurred, that is, if an image is not completely formed so as to improve illuminance unevenness or the like, the size of the area on which the second irradiation light 202 is incident is slightly larger than the size of the second light-emitting surface 11-2 multiplied by the magnification β. In a case where the size of the first light-emitting surface 11-1 is substantially equal to the size of the second light-emitting surface 11-2, the length in the X direction of the area on which the second irradiation light 202 is incident in the irradiation region 200 is substantially equal to β×dx, and the length in the Y direction of the area on which the second irradiation light 202 is incident in the irradiation region 200 is substantially equal to β×dy.

With respect to the first irradiation light 201, the second irradiation light 202 is emitted at a position shifted in the X direction in the irradiation region 200 by a length corresponding to the amount of movement of the lens 2 from the position of the lens 2 in the state A to the position of the lens 2 in the state B. If the length (for example, β×dx) in the X direction of the area on which each of the first irradiation light 201 and the second irradiation light 202 is incident is greater than the length corresponding to the amount of movement of the lens 2 (for example, the distance S1 between the centers of the adjacent light-emitting parts), the position on which the first irradiation light 201 is incident and the position on which the second irradiation light 202 is incident greatly overlap with each other in the irradiation region 200. The controller 4 illustrated in FIG. 1 can perform control such that there is at least partial overlap between (i) a position on the irradiation region on which the first irradiation light 201, which is the light emitted from the first light-emitting part 10-1 and transmitted through the lens 2 before change in the relative position between the light source 1 and the lens 2, is incident and (ii) a position on the irradiation region on which the second irradiation light 202, which is the light emitted from the second light-emitting part 10-2 and transmitted through the lens 2 after the change in the relative position, is incident.

First mixed-color light 203 illustrated in FIG. 8C is light obtained by time-averaging the first irradiation light 201 and the second irradiation light 202 overlapping with each other in the irradiation region 200 within the exposure period Ts illustrated in each of FIG. 6 and FIG. 7. The phrase “time-averaging the first irradiation light 201 and the second irradiation light 202 overlapping with each other within the exposure period Ts” refers to additive color mixing. That is, the light having the first chromaticity and the light having the second chromaticity, in which the ratio of the amounts of the lights are adjusted, that are irradiated within a predetermined period of time are added together to obtain a mixed color. As a result, the color of the obtained light (the first mixed-color light 203 in this example) appears to be a color that is adjusted to a predetermined color. The color of the first mixed-color light 203 can be adjusted by adjusting the ratio of the amount of the first irradiation light 201 to the amount of the second irradiation light 202 within the exposure period Ts.

For example, by making the irradiation time of the first irradiation light 201 longer than the irradiation time of the second irradiation light 202 within the exposure period T, the light-emitting module 100 can irradiate the irradiation region 200 with the first mixed-color light 203 having a chromaticity closer to the first chromaticity than to the second chromaticity. On the other hand, by making the irradiation time of the second irradiation light 202 longer than the irradiation time of the first irradiation light 201, the light-emitting module 100 can irradiate the irradiation region 200 with the first mixed-color light 203 having a chromaticity closer to the second chromaticity than to the first chromaticity. Alternatively, by making the drive current of the first light-emitting part 10-1 for emitting the first irradiation light 201 greater than the drive current of the second light-emitting part 10-2 for emitting the second irradiation light 202 within the exposure period Ts, the light-emitting module 100 can irradiate the irradiation region 200 with the first mixed-color light 203 having a chromaticity closer to the first chromaticity than to the second chromaticity. Further, by making the drive current of the second light-emitting part 10-2 for emitting the second irradiation light 202 greater than the drive current of the first light-emitting part 10-1 for emitting the first irradiation light 201, the light-emitting module 100 can irradiate the irradiation region 200 with the first mixed-color light 203 having a chromaticity closer to the second chromaticity than to the first chromaticity. The light-emitting module 100 can adjust the drive power of each of the plurality of light-emitting parts 10 within the exposure period Ts.

The light-emitting module 100 can emit any one of the light having the first chromaticity, the light having the second chromaticity, or the mixed-color light of the first chromaticity and the second chromaticity by controlling the relative movement between the light source 1 and the lens 2 and the light emission of the plurality of light-emitting parts 10 within the exposure period T. Further, the light-emitting module 100 can appropriately change the color of the mixed-color light of the first chromaticity and the second chromaticity to a color close to the first chromaticity or to a color close to the second chromaticity. The color of the mixed-color light of the first chromaticity and the second chromaticity is an example of a predetermined color.

Light emitted from the light-emitting module 100, that is, each of the first irradiation light 201, the second irradiation light 202, and the first mixed-color light 203 is not limited to light emitted to a rectangular region in the irradiation region 200, and can be light emitted to a region having a circular shape, an elliptical shape, or the like. In addition, light emitted from each of the plurality of light-emitting parts 10 can partially overlap with light from an adjacent light-emitting part 10.

### Main Effects of Light-Emitting Module 100

As described above, the light-emitting module 100 according to the present embodiment includes: the light source 1 that includes the plurality of light-emitting parts 10 having the respective light-emitting surfaces 11 and including the first light-emitting part 10-1 configured to emit light having a first chromaticity and the second light-emitting part 10-2 configured to emit light having a second chromaticity different from the first chromaticity; and the lens 2 configured to transmit light from the light source 1. Further, the light-emitting module 100 includes the actuator 3 configured to change the relative position between the light source 1 and the lens 2 in a direction intersecting the optical axis 20 of the lens 2, and the controller 4 configured to control light emission of each of the plurality of light-emitting parts 10 and the operation of the actuator 3. The controller 4 is configured to perform control such that, in an irradiation region, there is at least partial overlap between (i) a position on which light emitted from the first light-emitting part 10-1 and transmitted through the lens 2 is incident before the change in the relative position and (ii) a position on which light emitted from the second light-emitting part 10-2 and transmitted through the lens 2 is incident after the change in the relative position. As described above, in the present embodiment, at least a portion of the position on which light emitted from the first light-emitting part 10-1 and transmitted through the lens 2 is incident can overlap with at least a portion of the position on which the light emitted from the second light-emitting part 10-2 and transmitted through the lens 2 is incident. As a result of the lights partially overlapping with each other in the irradiation region, light having a color adjusted to a predetermined color can be emitted. Specifically, in a case where the light-emitting module 100 according to the present embodiment is used as a flash light source of the imaging device, reflected light of the light emitted from the first light-emitting part 10-1 and transmitted through the lens 2 is combined with reflected light of the light emitted from the second light-emitting part 10-2 and transmitted through the lens 2 on an image sensor, thereby obtaining light that appears as if its color is adjusted. Accordingly, light whose color appears to be adjusted can be produced in a pseudo manner. As described above, in the present embodiment, the light-emitting module 100 that can emit light having a color adjusted to a predetermined color can be provided.

For example, typically, a light-emitting module is required to emit light having a color adjusted to a predetermined color within a predetermined period of time such as an exposure period of an imaging device. In view of this, in the present embodiment, the light from the first light-emitting part 10-1 after being transmitted through the lens 2 can overlap with the light from the second light-emitting part 10-2 after being transmitted through the lens 2 by changing the relative position between the light source 1 and the lens 2. In this manner, with the one light-emitting module, the light from the first light-emitting part 10-1 after being transmitted through the lens 2 can overlap with the light from the second light-emitting part 10-2 after being transmitted through the lens 2. The color of light from the light-emitting module 100 can be adjusted to a desired color by causing the actuator 3 to change the relative position between the light source 1 and the lens 2, so that, as compared to when a plurality of light-emitting modules having different emission colors are used, the size of the light-emitting module 100 can be reduced and the number of parts of the light-emitting module 100 can be reduced. Further, the optical axes of two or more light-emitting parts can easily align with one another, which allows for reducing color unevenness of irradiation light.

In the present embodiment, the controller 4 can cause the plurality of light-emitting parts 10 to emit light within the movement period Tx1 during which the relative position between the light source 1 and the lens 2 is changed by the actuator 3. The light-emitting module 100 can increase the amount of irradiation light from the light-emitting module 100 by causing the plurality of light-emitting parts 10 to emit light within the movement period Tx1.

In the present embodiment, the controller 4 does not necessarily cause the plurality of light-emitting parts 10 to emit light within the movement period Tx1. By causing the plurality of light-emitting parts 10 not to emit light within the movement period Tx1, the light-emitting module 100 can suppress a color change of irradiation light during the movement of the lens 2, and thus can adjust the color of the irradiation light to a more desired color.

In the present embodiment, the controller 4 can perform control such that there is at least partial overlap within a predetermined period of time for exposure between (i) a position on which light emitted from the first light-emitting part 10-1 and transmitted through the lens 2 is incident before change in at least one of the relative position or the relative inclination of the lens 2 with respect to the light source 1 and (ii) a position on which light emitted from the second light-emitting part 10-2 and transmitted through the lens 2 is incident after the change in the at least one of the relative position or the relative inclination of the lens 2 with respect to the light source 1. The predetermined period of time is, for example, the exposure period of the imaging device. In this manner, light whose color appears to be adjusted can be produced in a pseudo manner. Thus, in the present embodiment, the light-emitting module 100 that can emit light having a color adjusted to a predetermined color can be provided.

### First Modification of First Embodiment

A first modification of the first embodiment will be described. The same names and reference numerals as those in the first embodiment described above denote the same or similar members, and a detailed description thereof will be omitted as appropriate. Further, a description and illustration of the same components as those of the light-emitting module 100 will be omitted as appropriate, and mainly the differences from the light-emitting module 100 will be described. The same applies to each of embodiments and modifications described below.

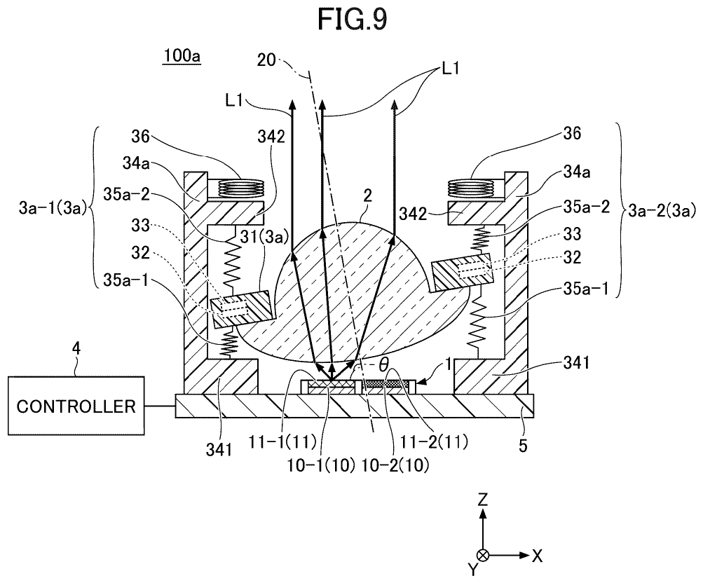

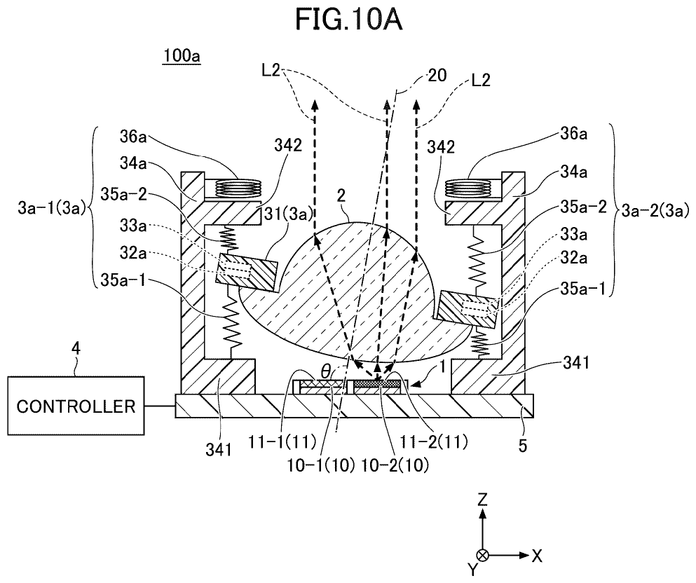

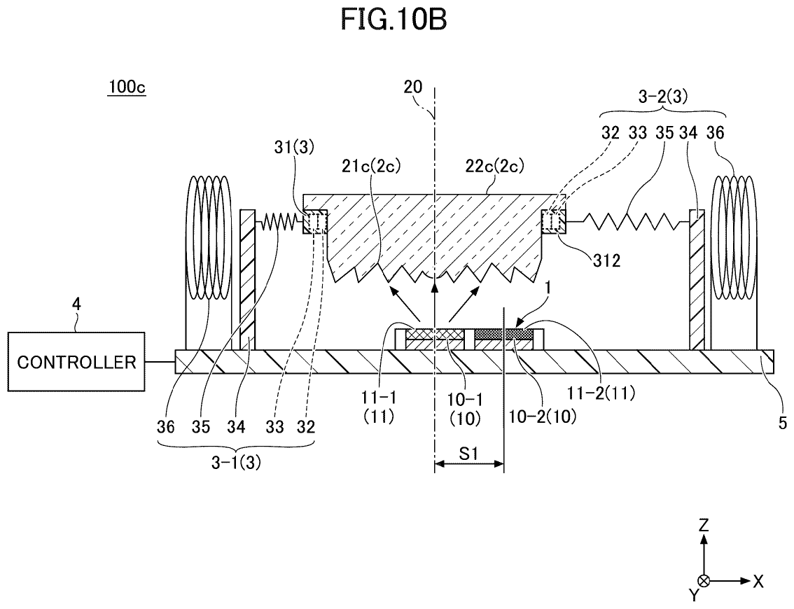

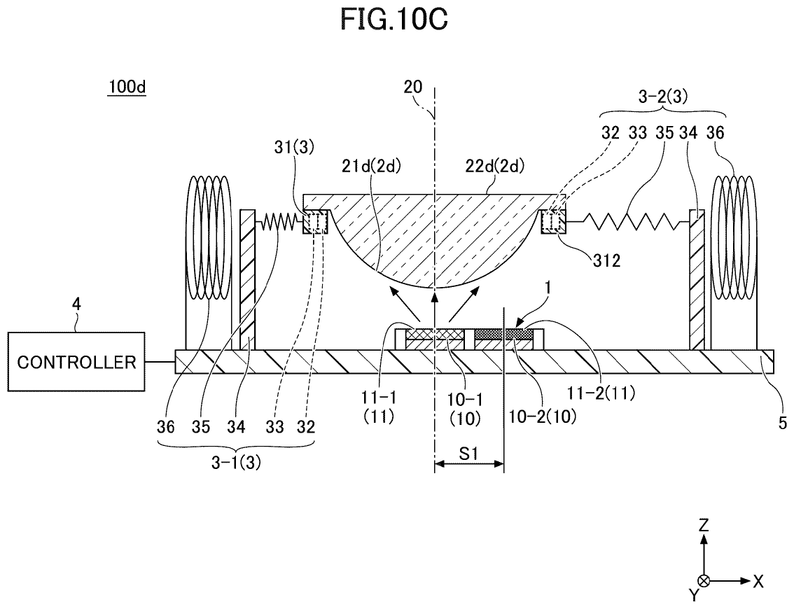

FIG. 9 is a cross-sectional view illustrating an example of a configuration of a light-emitting module 100a according to the first modification of the first embodiment. FIG. 10A is a cross-sectional view of the light-emitting module 100a after the inclination angle of the optical axis 20 of the lens 2 is changed from the state of FIG. 9. The light-emitting module 100a includes an actuator 3a configured to change a relative inclination θ of the optical axis 20 of the lens 2 with respect to a light-emitting surface 11 of a corresponding one of the plurality of light-emitting parts 10. The controller 4 performs control such that there is at least partial overlap between (i) a position on the irradiation position on which light emitted from the first light-emitting part 10-1 and transmitted through the lens 2 is incident before change in the relative inclination θ and (ii) a position on the irradiation position on which light emitted from the second light-emitting part 10-2 and transmitted through the lens 2 is incident after the change in the relative inclination θ.

As illustrated in FIG. 9 and FIG. 10A, the actuator 3a includes an electromagnetic actuator configured to change the relative inclination θ of the optical axis 20 of the lens 2 with respect to the light-emitting surface 11 by inclining the lens 2 relative to the light-emitting surface 11. The actuator 3a is provided on the surface on the +Z side of the light-emitting-part mounting substrate 5.

The actuator 3a includes a first actuator 3a-1 and a second actuator 3a-2. Each of the first actuator 3a-1 and the second actuator 3a-2 includes an N-pole magnet 32, an S-pole magnet 33, a support 34a, a first spring 35a-1, a second spring 35a-2, and a respective coil 36. In a cross-sectional view of the light-emitting module 100a, the N-pole magnet 32, the S-pole magnet 33, the support 3a, the first spring 34a-1, the second spring 35a-2, and the coil 36 included in the first actuator 35a-1 are arranged on the −X side relative to the optical axis 20 of the lens 2. The N-pole magnet 32, the S-pole magnet 33, the support 3a, the first spring 34a-1, the second spring 35a-2, and the coil 36 included in the second actuator 35a-2 are arranged on the +X side relative to the optical axis 20 of the lens 2.

The light-emitting module 100a includes the two supports 34a in the X direction, and the two supports 34a are fixed on the surface on the +Z side of the light-emitting-part mounting substrate 5. Each of the two supports 34a includes a first protrusion 341 and a second protrusion 342 that protrude toward the lens 2. In the support 34a, the first protrusion 341 is provided at a position different from the second protrusion 342 in the Z direction. The first protrusions 34 are provided on the surface on the +Z side of the light-emitting-part mounting substrate 5 and on the −Z side of the lens 2, and the second protrusions 342 are provided on the +Z side of the lens 2. A frame 31 is disposed between the first protrusions 341 and the second protrusions 342.

One end of each of the first springs 35a-1 is connected to a corresponding first protrusion 341, and the other end of each of the first springs 35a-1 is connected to the lower surface of the frame 31. One end of each of the second springs 35a-2 is connected to a corresponding second protrusion 342, and the other end of each of the second springs 35a-2 is connected to the upper surface of the frame 31. The two supports 34a support the frame 31 from both sides of the frame 31 in the X direction via the first springs 35a-1 and the second springs 35a-2. The two N-pole magnets 32 and the two S-pole magnets 33 are fixed inside the frame 31. In the frame 31, the S-pole magnets 33 are located on the upper side (the +Z side) of the respective N-pole magnets 32. The two coils 36 face the S-pole magnets 33 with the second protrusions 342 and the second springs 35a-2 interposed between the coils 36 and the S-pole magnets 33, respectively. The actuator 3a moves the frame 31 in the −Z direction or the +Z direction by an electromagnetic force generated by a current flowing through each of the two coils 36.

As illustrated in FIG. 9, in the case of inclining the frame 31 such that the −X side of the frame 31 is lower than the +X side of the frame 31 (the −X side of the frame 31 is located on the −Z side relative to the +X side of the frame 31), the first actuator 3a-1 moves the frame 31 further away from the coil 36, and the second actuator 3a-2 moves the frame 31 closer to the coil 36. On the other hand, as illustrated in FIG. 10A, in the case of inclining the frame 31 such that the +X side of the frame 31 is lower than the −X side of the frame 31 (the +X side of the frame 31 is located on the −Z side relative to the −X side of the frame 31), the first actuator 3a-1 moves the frame 31 closer to the coil 36, and the second actuator 3a-2 moves the frame 31 further away from the coil 36. By inclining the frame 31, the actuator 3a can incline the optical axis 20 of the lens 2 that is positioned substantially parallel to the Z-axis (in other words, the optical axis of each of the light-emitting parts 10 of the light source 1). That is, the actuator 3a can change the relative inclination θ of the lens 2 with respect to the light-emitting surface 11 of the corresponding one of the light-emitting parts 10 of the light source 1 fixed to the light-emitting-part mounting substrate 5.

The first springs 35a-1 and the second springs 35a-2 are elastic members that can expand and contract along the Z direction. The first springs 35a-1 and the second springs 35a-2 limit excessive movement of the frame 31, and impart a restoring force to the frame 31 that causes the frame 31 to return to its initial position. Any appropriate material can be used as the material of the first springs 35a-1 and the second springs 35a-2, and a metal material, a resin material, or the like can be used. The number of the first springs 35a-1 and the number of the two second springs 35a-2 can be any appropriate number.

The magnitude of an electromagnetic force to be generated changes in accordance with the amount of the drive current flowing through each of the two coils 36, and thus the inclination angle of the optical axis 20 of the lens 2 with respect to the light-emitting surface 11 changes. Further, the direction of an electromagnetic force to be generated changes in accordance with the direction of the drive current flowing through each of the two coils 36, and thus the direction in which the lens 2 is inclined changes.

In the present embodiment, by changing the relative inclination θ of the optical axis 20 of the lens 2 with respect to the light-emitting surface 11, the actuator 3a can switch between a state C (a state of FIG. 9) in which light L1 emitted from the first light-emitting part 10-1 and transmitted through the lens 2 is substantially orthogonal to the first light-emitting surface 11-1 and a state D (state of FIG. 10A) in which light L2 emitted from the second light-emitting part 10-2 and transmitted through the lens 2 is substantially orthogonal to the second light-emitting surface 11-2. As used herein, the term “substantially orthogonal” means that the light emitted from the first light-emitting part 10-1 and the light emitted from the second light-emitting part 10-2 can be deviated from the orthogonal state as long as most of the incident position of the light emitted from the first light-emitting part 10-1 and most of the incident position of the light emitted from the second light-emitting part 10-2 overlap with each other in the irradiation region. The driving method of the actuator 3a is not limited to the electromagnetic method, and can be another driving method such as a piezoelectric method or an ultrasonic method.

The controller 4 of the light-emitting module 100a can cause the drive control unit 42 illustrated in FIG. 5 to control the actuator 3a so as to change the relative inclination θ of the optical axis 20 of the lens 2 with respect to the light-emitting surface 11.

The light-emitting module 100a according to the first modification of the first embodiment can also exhibit the same effects as those of the light-emitting module 100 according to the first embodiment. The light-emitting module 100a can change both the relative inclination θ of the optical axis 20 of the lens 2 with respect to the light-emitting surface 11 and the relative position between the light source 1 and the lens 2 in a direction intersecting the optical axis 20 of the lens 2. The actuator 3a can include three or more sets each including an N-pole magnet 32, a S-pole magnet 33, a first spring 35a-1, a second spring 35a-2, and a coil 36, and can incline the frame 31 (in other words, the optical axis 20 of the lens 2) by changing the positions of three or more support points in the Z direction. The actuator 3a can include one or more sets each including an N-pole magnet 32, a S-pole magnet 33, a first spring 35a-1, a second spring 35a-2, and a coil 36, and can incline the frame 31 (in other words, the optical axis 20 of the lens 2) by changing the positions of one or more support points in the Z direction.

### Second Modification of First Embodiment

FIG. 10B is a cross-sectional view illustrating an example of a configuration of a light-emitting module 100c according to a second modification of the first embodiment. The light-emitting module 100c includes a Fresnel lens 2c. In the Fresnel lens 2c, an incident surface of light from the light source 1 is a Fresnel lens surface 21c, and an exit surface of the light from the light source 1 is a flat surface 22c. By setting the exit surface of the light to be the flat surface 22c, the thickness of the Fresnel lens 2c can be reduced as compared to that of a biconvex single lens, and the aesthetic appearance of the light-emitting module 100c can be improved. However, in the Fresnel lens 2c, the incident surface can be a flat surface and the exit surface can be a Fresnel lens surface.

### Third Modification of First Embodiment

FIG. 10C is a cross-sectional view illustrating an example of a configuration of a light-emitting module 100d according to a third modification of the first embodiment. The light-emitting module 100d includes a plano-convex lens 2d. In the plano-convex lens 2d, an incident surface of light from the light source 1 is a convex surface 21d and an exit surface of the light from the light source 1 is a flat surface 22d. By setting the exit surface of the light to be the flat surface 22d, the thickness of the plano-convex lens 2d can be reduced as compared to that of a biconvex single lens. However, in the plano-convex lens 2d, the incident surface can be a flat surface and the exit surface can be a convex surface.

The light-emitting module according to the first embodiment can include a lens in which the incident surface of the light from the light source 1 is a convex surface and the exit surface of the light from the light source 1 is a Fresnel lens surface. Alternatively, the light-emitting module according to the first embodiment can include a lens in which the incident surface of the light from the light source 1 is a Fresnel lens surface and the exit surface of the light from the light source 1 is a convex surface.

### Second Embodiment

### Example Configuration of Light-Emitting Module 100b

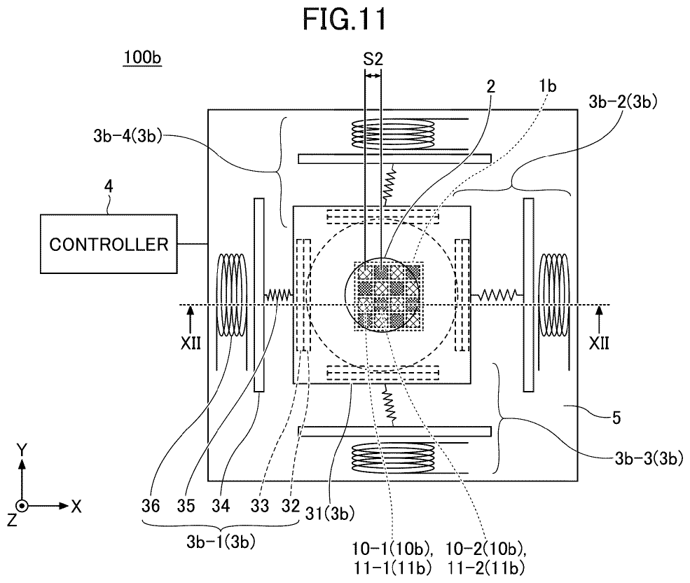

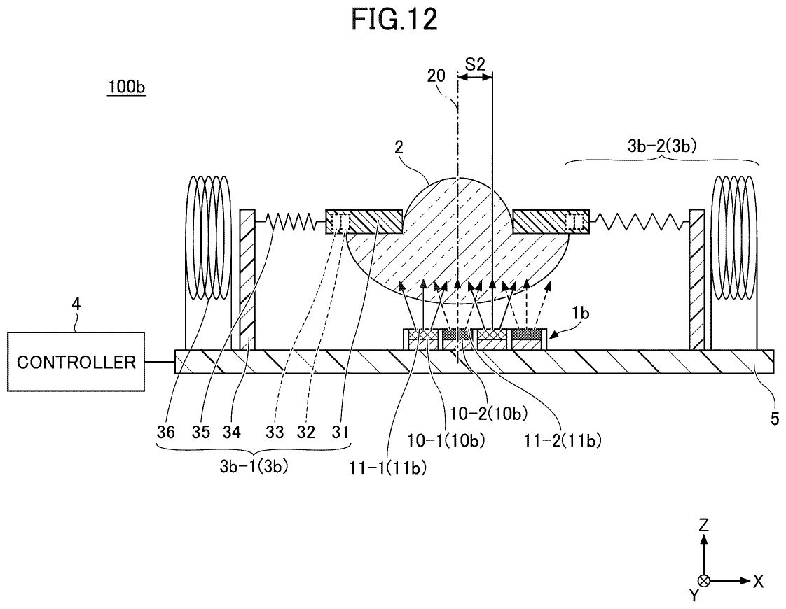

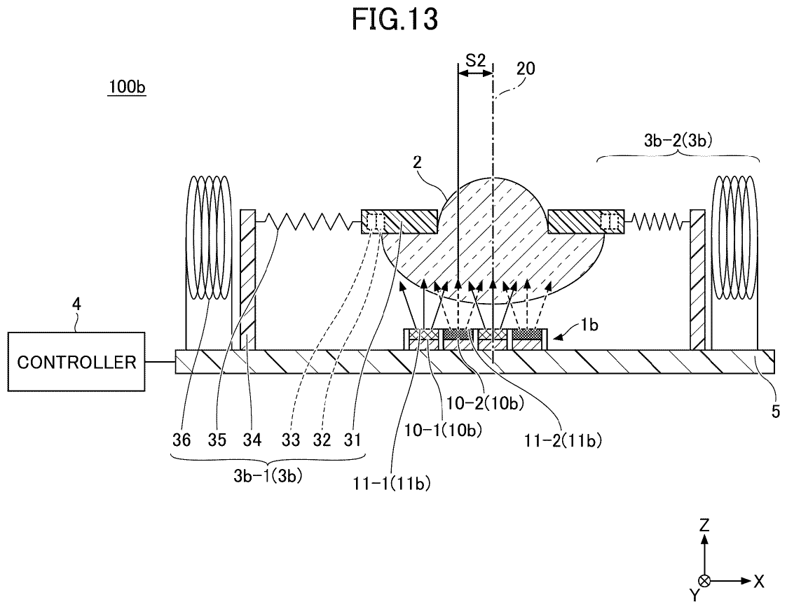

A configuration of a light-emitting module 100b according to a second embodiment will be described with reference to FIG. 11 to FIG. 13. FIG. 11 is a top view illustrating an example of the configuration of the light-emitting module 100b. FIG. 12 is a cross-sectional view taken along line XII-XII of FIG. 11. FIG. 13 is a cross-sectional view illustrating an example of the light-emitting module 100b after the lens 2 is moved in the +X direction from the state of FIG. 12.

As illustrated in FIG. 11 and FIG. 12, the light-emitting module 100b includes a light source 1b and an actuator 3b.

### (Light Source 1b)

The light source 1b includes a plurality of light-emitting parts 10b including eight first light-emitting parts 10-1 and eight second light-emitting parts 10-2. In other words, the light source 1b includes two or more first light-emitting parts 10-1 and two or more second light-emitting parts 10-2. The plurality of light-emitting parts 10b are arranged in a grid pattern in the X direction and the Y direction in a top view. The X direction is an example of the first direction. The Y direction is an example of the second direction.

The plurality of light-emitting parts 10b are arranged such that first light-emitting parts 10-1 and second light-emitting parts 10-2 are alternately arranged in the X direction. In addition, the plurality of light-emitting parts 10b are arranged such that first light-emitting parts 10-1 and second light-emitting parts 10-2 are alternately arranged in the Y direction. Specifically, the plurality of light-emitting parts 10b are arranged such that two first light-emitting parts 10-1 and two second light-emitting parts 10-2 are alternately arranged in the X direction, and two first light-emitting parts 10-1 and two second light-emitting parts 10-2 are alternately arranged in the Y direction. By arranging the plurality of light-emitting parts without changing the total light-emitting area of the light source (in other words, by dividing the light-emitting surface of a single light source), a distance S2 between the centers of adjacent light-emitting parts of the plurality of light-emitting parts can be reduced (for example, the distance S1>the distance S2), and the distance by which the light source 1b is moved by the actuator 3b, which will be described below, can be reduced. The plurality of light-emitting parts 10b have a plurality of light-emitting surfaces 11b. The plurality of light-emitting surfaces 11b include first light-emitting surfaces 11-1 and second light-emitting surfaces 11-2.

The light source 1b emits light from the plurality of light-emitting parts 10b toward the lens 2 located on the +Z side of the light source 1b. The number of first light-emitting parts 10-1 and/or the number of second light-emitting parts 10-2 included in the light source 1b is two or more. The number of first light-emitting parts 10-1 and the number of second light-emitting parts 10-2 can be adjusted as appropriate according to the application or the like of the light-emitting module 100b.

### (Actuator 3b)

As illustrated in FIG. 11 to FIG. 13, the actuator 3b includes an electromagnetic actuator configured to move the lens 2 relative to the light source 1b along the X direction or the Y direction. The actuator 3b is provided on the surface on the +Z side of the light-emitting-part mounting substrate 5.

The actuator 3b includes a frame 31, a first actuator 3b-1, a second actuator 3b-2, a third actuator 3b-3, and a fourth actuator 3b-4. Each of the first actuator 3b-1, the second actuator 3b-2, the third actuator 3b-3, and the fourth actuator 3b-4 includes a N-pole magnet 32, a S-pole magnet 33, a support 34, a spring 35, and a coil 36. In FIG. 11 to FIG. 13, in order to prevent the drawings from being complicated, the reference numerals of the N-pole magnet 32, the S-pole magnet 33, the support 34, the spring 35, and the coil 36 included in the first actuator 3b-1 among the first actuator 3b-1, the third actuator 3b-3, and the fourth actuator 3b-4 are illustrated.

The N-pole magnet 32, the S-pole magnet 33, the support 34, the spring 35, and the coil 36 included in the first actuator 3b-1 are arranged on the −X side of the lens 2. The N-pole magnet 32, the S-pole magnet 33, the support 34, the spring 35, and the coil 36 included in the second actuator 3b-2 are arranged on the +X side of the lens 2. The N-pole magnet 32, the S-pole magnet 33, the support 34, the spring 35, and the coil 36 included in the third actuator 3b-3 are arranged on the −Y side the lens 2. The N-pole magnet 32, the S-pole magnet 33, the support 34, the spring 35, and the coil 36 included in the fourth actuator 3b-4 are arranged on the +Y side of the lens 2.

The frame 31 supports the lens 2. The four supports 34 are fixed on the surface on the +Z side of the light-emitting-part mounting substrate 5, and support the frame 31 from both sides of the frame 31 in each of the X direction and the Y direction via the springs 35. The four N-pole magnets 32 and the four S-pole magnets 33 are fixed inside the frame 31. In the frame 31, the S-pole magnets 33 is located outward of the N-pole magnets 32.

The four coils 36 face the S-pole magnets 33 with the supports 34 and the springs 35 interposed between the coils 36 and the S-pole magnets 33. The actuator 3b moves the frame 31 in the −X direction, the +X direction, the −Y direction, and the +Y direction by an electromagnetic force generated by a current flowing through each of the four coils 36.

As illustrated in FIG. 12, in the case of moving the frame 31 in the −X direction, the first actuator 3b-1 moves the frame 31 closer to the coil 36, and the second actuator 3b-2 moves the frame 31 farther away from the coil 36. As illustrated in FIG. 13, in the case of moving the frame 31 in the +X direction, the first actuator 3b-1 moves the frame 31 farther away from the coil 36, and the second actuator 3b-2 moves the frame 31 closer to the coil 36. Further, in the case of moving the frame 31 in the −Y direction, the third actuator 3b-3 moves the frame 31 closer to the coil 36, and the fourth actuator 3b-4 moves the frame 31 further away from the coil 36. In the case of moving the frame 31 in the +Y direction, the third actuator 3b-3 moves the frame 31 farther away from the coil 36, and the fourth actuator 3b-4 moves the frame 31 closer to the coil 36. The actuator 3b can change the relative position of the lens 2 with respect to the light source 1b fixed to the light-emitting-part mounting substrate 5 by moving the frame 31.

In response to a drive current being supplied from the controller 4 to each of the four coils 36, an electromagnetic force is generated by the action of the four N-pole magnets 32, the four S-pole magnets 33, and the four coils 36. The frame 31 moves according to a direction in which the generated electromagnetic force acts on the frame 31. The magnitude of an electromagnetic force to be generated changes in accordance with the amount of the drive current flowing through each of the four coils 36, and thus the amount of movement of the lens 2 changes. Further, the direction of an electromagnetic force to be generated changes in accordance with the direction of the drive current flowing through each of the four coils 36, and thus the direction of movement of the lens 2 changes.

In the present embodiment, the actuator 3b moves the lens 2 in the X direction by a distance substantially equal to the distance S2 between the centers of the adjacent light-emitting parts 10b of the plurality of light-emitting parts 10b. Accordingly, the actuator 3b can switch between a state E in which the optical axis 20 of the lens 2 intersects a second light-emitting surface 11-2, that is, the state of FIG. 12 and a state F in which the optical axis 20 of the lens 2 intersects a first light-emitting surface 11-1, that is, the state of in FIG. 13. In the state E, the optical axis 20 of the lens 2 can intersect any one of the eight second light-emitting surfaces 11-2. Further, in the state F, the optical axis 20 of the lens 2 can intersect any one of the eight first light-emitting surfaces 11-1. The driving method of the actuator 3b is not limited to the electromagnetic method, and can be another driving method such as a piezoelectric method or an ultrasonic method.

The controller 4 of the light-emitting module 100b can control the actuator 3b such that the drive control unit 42 illustrated in FIG. 5 moves the lens 2 along the X direction or the Y direction relative to the light source 3b. Further, the controller 4 of the light-emitting module 100b can cause the actuator 3b to change the relative position between the light source 1b and the lens 2 a plurality of times within the exposure period of the imaging device. By changing the relative position a plurality of times, light that can be received by an imaging element of the imaging device can be integrated, and an influence of temporary illuminance unevenness caused by noise or the like of the imaging element can be reduced.

The imaging device including the light-emitting module 100b can store, in a storage, an image captured by using light having the first chromaticity from the light-emitting module 100b and an image captured by using light having the second chromaticity from the light-emitting module 100b. Subsequently, the imaging device can read the images from the storage, combine the images, and perform image processing for adjusting the color of the combined images so as to obtain an image having a color adjusted to a desired color. By performing image processing for adjusting the color of images captured by using lights having two different chromaticities, the degree of freedom in adjusting the color can be increased. Further, by performing image processing for adjusting the color of images captured by using lights having two different chromaticities, the image processing can be simplified and an image of a more natural color can be obtained, as compared to the case of image processing for adjusting the color of an image captured by using light having one chromaticity. However, in the present embodiment, because the imaging device including the light-emitting module 100b performs photographing by using light whose color is adjusted by integrating light having the first chromaticity and light having the second chromaticity without using image processing, a process of storing two images in the storage and image processing for adjusting the color do not need to be performed, and thus the processing load of the imaging device can be reduced.

The operation of the light-emitting module 100b is the same as the operation described above with reference to FIG. 6 and FIG. 7, except that the lens 2 can be moved relative to the light source 1b in both the X direction and the Y direction and the amount of movement corresponds to the distance S2 between the centers of the adjacent light-emitting parts.

### Examples of Irradiation light from Light-Emitting Module 100b

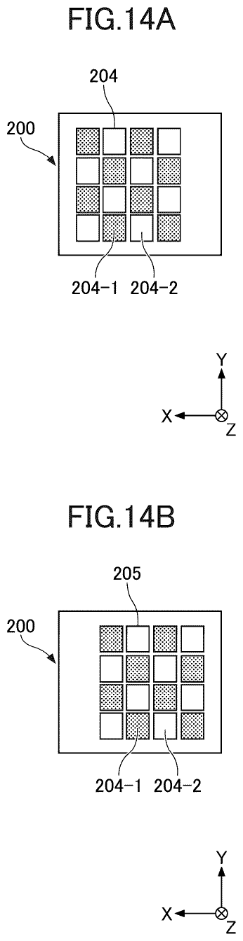

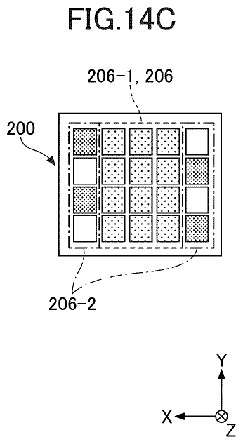

FIG. 14A and FIG. 14B are diagrams illustrating examples of irradiation light from the light-emitting module 100b. FIG. 14A is a diagram illustrating an example of irradiation light in the state E illustrated in FIG. 12. FIG. 14B is a diagram illustrating an example of irradiation light in the state F illustrated in FIG. 13. FIG. 14C is a diagram illustrating an example of mixed-color light obtained by mixing the irradiation light of FIG. 14A and the irradiation light of FIG. 14B. Each of FIG. 14A to FIG. 14C depicts the irradiation light when the irradiation region 200 is viewed in a direction in which the light-emitting module 100b is located.

As illustrated in FIG. 14A, in the state E, the irradiation region 200 is irradiated with third irradiation light 204 including light 204-1 having the first chromaticity emitted from a plurality of first light-emitting parts 10-1 and light 204-2 having the second chromaticity emitted from a plurality of second light-emitting parts 10-2. The size of the third irradiation light 204 in the irradiation region 200 is substantially equal to the size of the light source 1b multiplied by the magnification β.

As illustrated in FIG. 14B, in the state F, the irradiation region 200 is irradiated with fourth irradiation light 204 including the light 204-1 having the first chromaticity emitted from the plurality of first light-emitting parts 10-1 and the light 204-2 having the second chromaticity emitted from the plurality of second light-emitting parts 10-2. The fourth irradiation light 205 is irradiated at a position shifted in the −X direction with respect to the third irradiation light 204 by the distance S2. The size of the fourth irradiation light 205 in the irradiation region 200 is substantially equal to the size of the light source 1b multiplied by the magnification β.

The controller 4 illustrated in FIG. 11 can perform control such that there is at least partial overlap between (i) a position in the irradiation region on which the light 204-1 having the first chromaticity, which is the light emitted from the first light-emitting parts 10-1 and transmitted through the lens 2, is incident before a change in the relative position between the light source 1b and the lens 2 and (ii) a position in the irradiation region on which the light 204-2 having the second chromaticity, which is the light emitting the second light-emitting parts 10-2 and transmitted through the lens 2, is incident after the change in the relative position.

The irradiation region 200 illustrated in FIG. 14C includes a first region 206-1 and a second region 206-2. The first region 206-1 is a region where the incident position of light from the first light-emitting parts 10-1 and the incident position of light from the second light-emitting parts 10-2 overlap with each other within the exposure period Ts during which the relative position between the light source 1b and the lens 2 is changed by the actuator 3b. The second region 206-2 is a region different from the first region 206-1 and including sub-regions each irradiated with either light from a first light-emitting part 10-1 or light from a second light-emitting part 10-2 within the exposure period Ts.

The incident position of the third irradiation light 204 and the incident position of the fourth irradiation light 205 overlap with each other in the first region 206-1 and are time-averaged in the exposure period Ts, and as a result, second mixed-color light 206 is obtained. The color of the second mixed-color light 206 can be adjusted by adjusting the ratio between the amount of the third irradiation light 204 and the amount of the fourth irradiation light 205 within the exposure period Ts. This adjusting method is the same as the method of adjusting the color of the first mixed-color light 203 described in the first embodiment.

In FIG. 14C, the color of light emitted to the second region 206-2 is unable to be adjusted, and thus, color unevenness would occur. For this reason, the controller 4 of the light-emitting module 100b preferably causes light-emitting parts that are to emit light to the second region 206-2 among the plurality of light-emitting parts 10b of the light source 1b not to emit light. Alternatively, it is preferable that the light source 1b includes additional light-emitting parts around the periphery of a light source region corresponding to the target irradiation region 200 so as to correct color unevenness.

The controller 4 of the light-emitting module 100b can selectively cause at least one of the plurality of light-emitting parts 10b to emit light, and can also individually control the amount of light from each of the plurality of light-emitting parts 10b by controlling at least one of a drive current, a drive voltage, or a light emission period of time of each of the plurality of light-emitting parts 10b. With this configuration, the light-emitting module 100b can partially irradiate the irradiation region 200 with the second mixed-color light 206 having an adjusted color. As used herein, partial irradiation means that the irradiation region 200 is partially irradiated with light from the light-emitting module 100b. The light-emitting module 100b can appropriately change the position that is partially irradiated within the irradiation region 200. The light source 1b can perform color adjustment when including at least two light-emitting parts, and can perform partial irradiation with color-adjusted light when including at least four light-emitting parts.

### Main Effects of Light-Emitting Module 100b

As described above, in the light-emitting module 100b, the plurality of light-emitting parts 10b are arranged in a grid pattern in the first direction (X direction) and the second direction (Y direction) intersecting the first direction in a top view. Further, the lens 2 moves relative to the light source 1b along the X direction or the Y direction. With this configuration, the same effects as those of the first embodiment described above can be obtained. The light-emitting module 100b can change the relative inclination θ of the optical axis 20 of the lens 2 with respect to a light-emitting surface 11b. Further, the light-emitting module 100b can change both the relative inclination θ and the relative position between the light source 1b and the lens 2 in a direction along the light-emitting surface 11b (or a direction intersecting the optical axis 20 of the lens 2). The same applies to each of modifications described below.

### Modifications of Second Embodiment

### First Modification

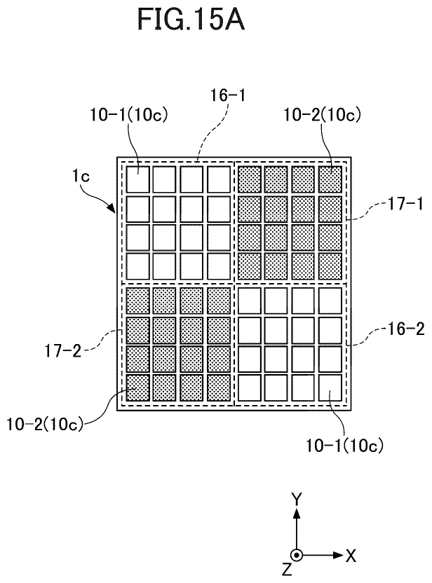

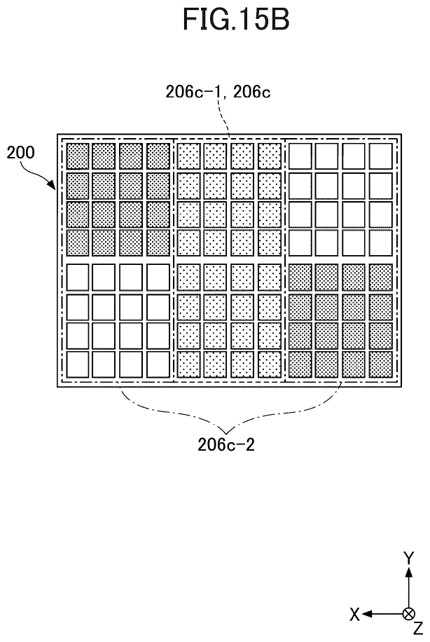

FIG. 15A is a diagram illustrating an example of a light source 1c according to a first modification of the second embodiment. FIG. 15B is a diagram illustrating an example of mixed-color light from the light source 1c. The light source 1c includes a plurality of light-emitting parts 10c. The plurality of light-emitting parts 10c include a plurality of first light-emitting parts 10-1 and a plurality of second light-emitting parts 10-2. In the present modification, the plurality of light-emitting parts 10c include sixty-four light-emitting parts. The number of the first light-emitting parts 10-1 is thirty-two, and the number of the second light-emitting parts 10-2 is thirty-two. Irradiation light emitted from the light source 1c is point-symmetric with respect to the center of the lens 2. FIG. 15B illustrates the irradiation region 200 when viewed from the −Z side toward the +Z side. Therefore, in FIG. 15B, the arrangement of the irradiation light from the first light-emitting parts 10-1 and the second light-emitting parts 10-2 in the irradiation region 200 is reversed with respect to the arrangement of the irradiation light from the first light-emitting parts 10-1 and the second light-emitting parts 10-2 in the light source 1c. The same applies to each of modifications described below.

A first light-emitting part group 16-1 consists of sixteen first light-emitting parts 10-1. The first light-emitting part group 16-2 consists of sixteen first light-emitting parts 10-1. A second light-emitting part group 17-1 consists of sixteen second light-emitting parts 10-2. A second light-emitting part group 17-2 consists of sixteen second light-emitting parts 10-2.

The first light-emitting part group 16-1 and the second light-emitting part group 17-1 are arranged adjacent to each other in the X direction. The second light-emitting part group 17-2 and the first light-emitting part group 16-2 are arranged adjacent to each other in the X direction. The first light-emitting part group 16-1 and the second light-emitting part group 17-2 are arranged adjacent to each other in the Y direction. The second light-emitting part group 17-1 and the first light-emitting part group 16-2 are arranged adjacent to each other in the Y direction.

In the present embodiment, the lens 2 moves once in the X direction relative to the light source 1c by a distance corresponding to four times a distance S2 between the centers of adjacent light-emitting parts of the plurality of light-emitting parts 10c. The distance of the relative movement of the lens 2 is not limited to four times the distance S2 between the centers of the adjacent light-emitting parts of the plurality of light-emitting parts 10c, and can be a natural number multiple of the distance S2. The distance of the relative movement of the lens 2 can be changed as appropriate in accordance with the number of the first light-emitting parts 10-1 included in the first light-emitting part group 16-1, the number of the second light-emitting parts 10-2 included in the second light-emitting part group 17-1, and the like. The relative movement of the lens 2 allows second mixed-color light 206c having an adjusted color to be obtained in the irradiation region 200. By causing the lens 2 to move relative to the light source 1c by a natural number multiple of the distance S2, the light-emitting module 100b can switch between the chromaticities of light extracted from the light source 1c.

The irradiation region 200 includes a first region 206c-1 and a second region 206c-2. The first region 206c-1 is a region where an incident position of light from the first light-emitting parts 10-1 and an incident position light from the second light-emitting parts 10-2 overlap with each other within the exposure period Ts during which the relative position between the light source 1c and the lens 2 is changed by the actuator 3b. The second mixed-color light 206c is obtained in the first region 206c-1. The second region 206c-2 is a region different from the first region 206c-1 and having regions each irradiated with either light from a first light-emitting part 10-1 or light from a second light-emitting part 10-2 within the exposure period Ts. The lens 2 can be moved once in the Y direction relative to the light source 1c by a distance corresponding to four times the distance S2 between the centers of the adjacent light-emitting parts of the plurality of light-emitting parts 10c.

### Second Modification

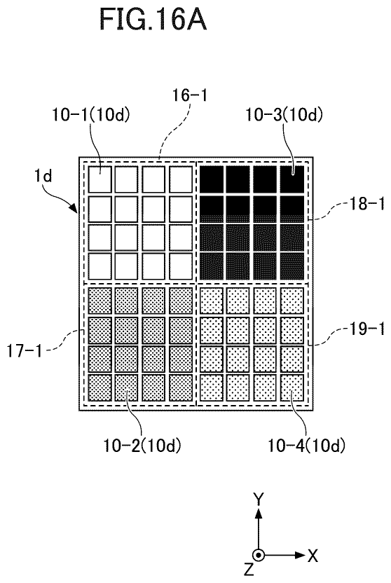

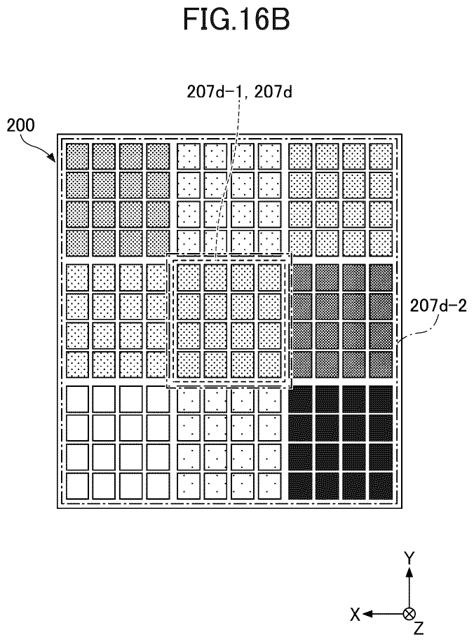

FIG. 16A is a diagram illustrating an example of a light source 1d according to a second modification of the second embodiment. FIG. 16B is a diagram illustrating an example of mixed-color light from the light source 1d. The light source 1d includes a plurality of light-emitting parts 10d. The plurality of light-emitting parts 10d include a plurality of first light-emitting parts 10-1, a plurality of second light-emitting parts 10-2, a plurality of third light-emitting parts 10-3, and a plurality of fourth light-emitting parts 10-4. The third light-emitting parts 10-3 emit light having a third chromaticity other than light having the first chromaticity and light having the second chromaticity. The fourth light-emitting parts 10-4 emit light having a fourth chromaticity other than the light having the first chromaticity and the light having the second chromaticity. Each of the third light-emitting parts 10-3 and the fourth light-emitting parts 10-4 is an example of a “third light-emitting part configured to emit light having a third chromaticity other than the light having the first chromaticity and the light having the second chromaticity.”

In the present modification, the plurality of light-emitting parts 10d include sixty-four light-emitting parts. A first light-emitting part group 16-1 consists of sixteen first light-emitting parts 10-1. A second light-emitting part group 17-1 consists of sixteen second light-emitting parts 10-2. A third light-emitting part group 18-1 consists of sixteen third light-emitting parts 10-3. A fourth light-emitting part group 19-1 consists of sixteen fourth light-emitting parts 10-4.

The first light-emitting part group 16-1 and the third light-emitting part group 18-1 are arranged adjacent to each other in the X direction. The second light-emitting part group 17-1 and the fourth light-emitting part group 19-1 are arranged adjacent to each other in the X direction. The first light-emitting part group 16-1 and the second light-emitting part group 17-1 are arranged adjacent to each other in the Y direction. The third light-emitting part group 18-1 and the fourth light-emitting part group 19-1 are arranged adjacent to each other in the Y direction.

When the lens 2 is moved relative to the light source 1d two times in each of the X direction and the Y direction, that is, four times in total by a distance corresponding to four times a distance S2 between the centers of adjacent light-emitting part 10d of the plurality of light-emitting parts 10d, third mixed-color light 207d having an adjusted color is obtained in the irradiation region 200. The number of times of the relative movement of the lens 2 can be three or more.

The irradiation region 200 includes a third region 207d-1 and a fourth region 207d-2. The third region 207d-1 is a region where an incident position of light from the first light-emitting parts 10-1, an incident position of light from the second light-emitting parts 10-2, an incident position of light from the third light-emitting parts 10-3, and an incident position of light of the fourth light-emitting part 10-4 overlap with each other within the exposure period Ts during which the relative position between the light source 1d and the lens 2 is changed by the actuator 3b. The third mixed-color light 207d is obtained in the third region 207d-1. The fourth region 207d-2 is a region different from the third region 207d-1 and having regions each irradiated with one or two of light from the first light-emitting parts 10-1, light from the second light-emitting parts 10-2, light from the third light-emitting parts 10-3, and light from the fourth light-emitting parts 10-4 within the exposure period Ts.

### Third Modification

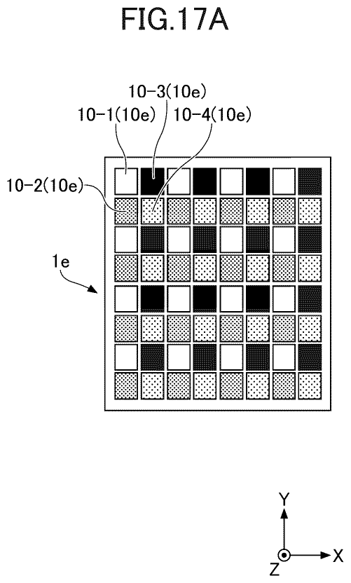

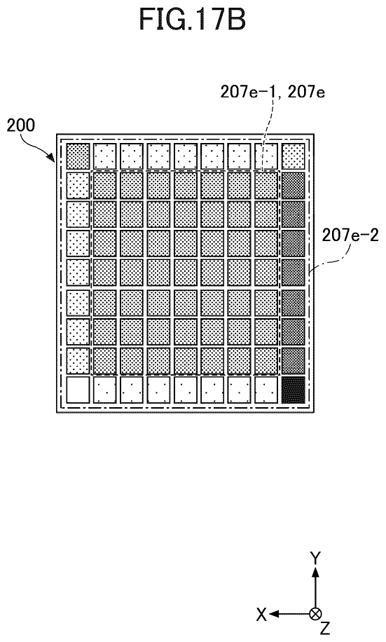

FIG. 17A is a diagram illustrating an example of a light source le according to a third modification of the second embodiment. FIG. 17B is a diagram illustrating an example of mixed-color light from the light source 1e. The light source le includes a plurality of light-emitting parts 10e. The plurality of light-emitting parts 10d include a plurality of first light-emitting parts 10-1, a plurality of second light-emitting parts 10-2, a plurality of third light-emitting parts 10-3, and a plurality of fourth light-emitting parts 10-4.

In the present modification, the plurality of light-emitting parts 10d include sixty four light-emitting parts. The number of the first light-emitting part 10-1 is sixteen, the number of the second light-emitting part 10-2 is sixteen, the number of the third light-emitting parts 10-3 is sixteen, and the number of the fourth light-emitting parts 10-4 is sixteen.

Four first light-emitting parts 10-1 and four third light-emitting parts 10-3 are alternately arranged in the X direction. Four second light-emitting parts 10-2 and four fourth light-emitting parts 10-4 are alternately arranged in the X direction. Four first light-emitting parts 10-1 and four second light-emitting parts 10-2 are alternately arranged in the Y direction. Four third light-emitting parts 10-3 and four fourth light-emitting parts 10-4 are alternately arranged in the Y direction.

When the lens 2 is moved once relative to the light source 1e in each of the X direction and the Y direction, more specifically, moves once in each of the +X direction, the −Y direction, and the −X direction in this order by a distance corresponding to a distance S2 between the centers of adjacent light-emitting parts of the plurality of light-emitting parts 10e, third mixed-color light 207e having an adjusted color is obtained in an irradiation region 200.

The irradiation region 200 includes a third region 207e-1 and a fourth region 207e-2. The third region 207e-1 is a region where an incident position of light from the first light-emitting parts 10-1, an incident position of light from the second light-emitting parts 10-2, an incident position of light from the third light-emitting parts 10-3, and an incident position of light from the fourth light-emitting parts 10-4 overlap with each other within the exposure period Ts during which the relative position between the light source 1e and the lens 2 is changed by the actuator 3b. The third mixed-color light 207e is obtained in the third region 207e-1. The fourth region 207e-2 is a region different from the third region 207e-1 and having regions each irradiated with one or two of light from a first light-emitting part 10-1, light from a second light-emitting part 10-2, light from a third light-emitting part 10-3, and light from a fourth light-emitting part 10-4 within the exposure period Ts.

In the present modification, the range of the mixed-color light whose color is adjustable in the irradiation region 200 can be expanded as compared to those of the first modification and the second modification described above.

In the first modification to the third modification described above, a method of adjusting the color of each of the second mixed-color light 206c, the third mixed-color light 207d, and the third mixed-color light 207e is the same as the method of adjusting the color of the first mixed-color light 203 described in the first embodiment. A preventive measure against color unevenness caused by light emitted to the second region 206c-2, the fourth region 207d-2, and the fourth region 207e-2 is the same as the preventive measure against color unevenness in the second region 206-2 described in the second embodiment. The light-emitting module 100b including the light source 1c, the light source 1d, or the light source 1e can perform partial irradiation.

In the first modification to the third modification described above, the lens 2 can be moved relative to any one of the light source 1c, the light source 1d, or the light source 1e in an oblique direction, that is, in a direction intersecting the X direction or the Y direction in a top view. Further, the lens 2 can be moved so as to circulate relative to any one of the light source 1c, the light source 1d, or the light source 1e. In the above cases, the color of mixed-color light can be adjusted.

In the second modification and the third modification described above, the controller 4 can perform control such that there is at least partial overlap between (i) a position in the irradiation region on which light emitted from the first light-emitting parts 10-1 and transmitted through the lens 2 is incident before a change in the relative position between the light source 1d or the light source 1e and the lens 2 and (ii) a position in the irradiation region on which light emitted from the second light-emitting parts 10-2 or the third light-emitting parts 10-3 and transmitted through the lens 2 is incident after the change in the relative position. The controller 4 does not necessarily cause light-emitting parts that are to emit light to the fourth region 207d-2, among the plurality of light-emitting parts 10d of the light source 1d, to emit light. The controller 4 does not necessarily cause light-emitting parts that are to emit light to the fourth region 207e-2, among the plurality of light-emitting parts 10e of the light source 1e, to emit light.

In addition to the first modification to the third modification described above, the plurality of light-emitting parts of the light source 1b can be arranged in a stripe pattern. In this case, for example, the light source 1b includes a plurality of first light-emitting part groups, in each of which a plurality of first light-emitting parts 10-1 are arranged in the Y direction, and a plurality of second light-emitting part groups, in each of which a plurality of second light-emitting parts 10-2 are arranged in the Y direction. The plurality of first light-emitting part groups and the plurality of second light-emitting part groups are alternately arranged in the X direction, and thus the plurality of light-emitting parts are arranged in a stripe pattern. Light-emitting parts of three or more colors can be arranged in a stripe pattern. The light source 1b can perform color adjustment as long as the light source 1b includes a plurality of light-emitting parts that can emit lights having different chromaticities, and causes the incident positions of the lights having different chromaticities to overlap with each other in the irradiation region by changing at least one of the relative position between the light source 1b and the lens 2 in a direction intersecting the optical axis 20 of the lens 2 or the relative inclination of the optical axis 20 of the lens 2 with respect to a light-emitting surface 11.

### Third Embodiment

Next, a light-emitting module according to a third embodiment will be described. The third embodiment differs from the first embodiment and the second embodiment in that at least two light-emitting parts configured to emit light having different colors are included, and the output ratio of the light-emitting parts is controlled such that light having a color corresponding to a desired time is emitted. The at least two light-emitting parts configured to emit light having different colors include at least one first light-emitting part configured to emit light having a first chromaticity and at least one second light-emitting part configured to emit light having a second chromaticity different from the first chromaticity.

### Example Configuration of Light-Emitting module 100e

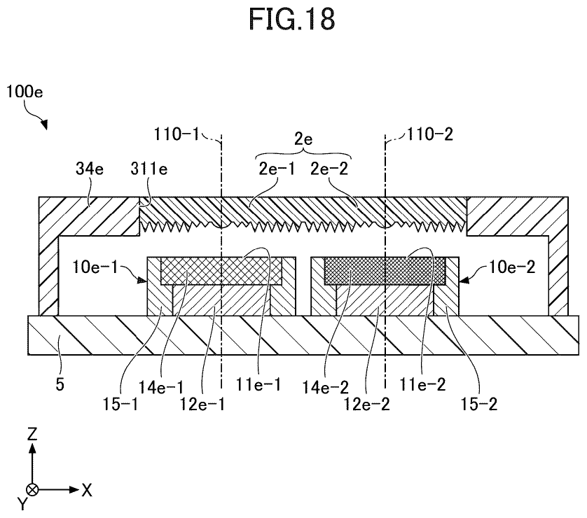

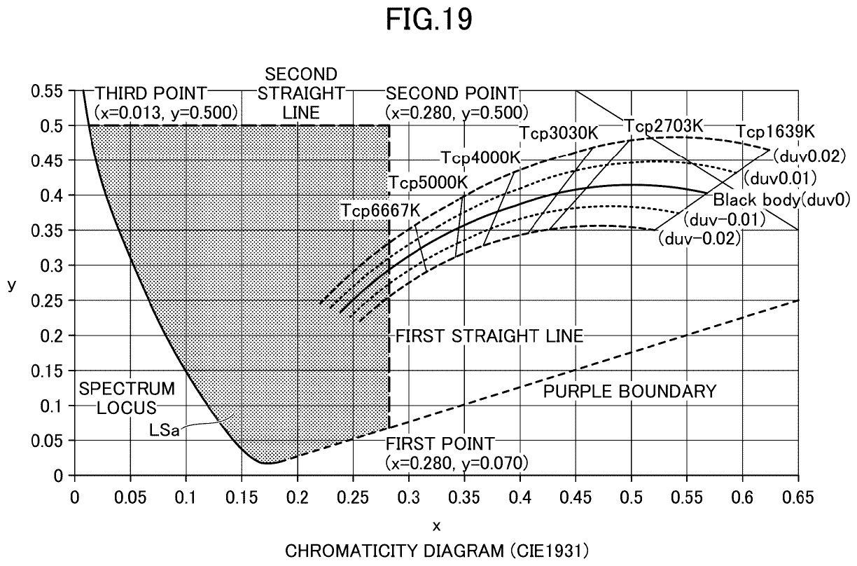

The light-emitting module according to the third embodiment will be described with reference to FIG. 18 and FIG. 19. FIG. 18 is a schematic cross-sectional view illustrating an example of a configuration of a light-emitting module 100e according to the third embodiment. FIG. 18 illustrates a cross section of the light-emitting module 100e taken along an imaginary plane including a central axis 110-1 of a first light-emitting surface 11e-1 of a first light-emitting part 10e-1 included in the light-emitting module 100e and a central axis 110-2 of a second light-emitting surface 11e-2 of a second light-emitting part 10e-2 included in the light-emitting module 100e. FIG. 19 is a part of a chromaticity diagram of the CIE1931 color space, which illustrates a light-emitting region LSa of the first light-emitting part, a blackbody locus (having duv of 0), and loci having color deviations duv of −0.02, −0.01, 0.01, and 0.02 from the blackbody locus at correlated color temperatures.

As illustrated in FIG. 18, the light-emitting module 100e includes the first light-emitting part 10e-1, the second light-emitting part 10e-2, and a lens 2e. Further, in the example illustrated in FIG. 18, the light-emitting module 100e includes a light-emitting-part mounting substrate 5 and a support 34e. The first light-emitting Part 10e-1 and the second light-emitting part 10e-2 are arranged on the surface on the +Z side of the light-emitting-part mounting substrate 5.

The first light-emitting part 10e-1 and the second light-emitting part 10e-2 correspond to the at least two light-emitting parts configured to emit light having different colors. The light-emitting module 100e can control the output ratio of the first light-emitting part 10e-1 and the second light-emitting part 10e-2 so as to emit light having a color corresponding to a desired time.

Light having a color corresponding to a desired time corresponds to, for example, sunlight at a desired time in 24 hours of a day. The color temperature of sunlight depends on the time during 24 hours of a day.

For example, sunlight has a high color temperature in the morning and appears bluish white, and has a low color temperature in the evening and appears orange. The color temperature of sunlight also varies according to the latitude on the earth. The light-emitting module 100e can emit light having a color temperature corresponding to the color temperature of sunlight at a desired time by controlling the output ratio of the first light-emitting part 10e-1 and the second light-emitting part 10e-2. Light having a color temperature corresponding to the color temperature of sunlight is, for example, light having substantially the same color temperature as the color temperature of sunlight.

In FIG. 18, an opening 311e is formed in the support 34e. The shape of the opening 311e in a top view is a substantially circular shape. The support 34e is disposed on the surface on the +Z side of the light-emitting-part mounting substrate 5. The lens 311e having a substantially circular shape in a top view is disposed inside the opening 2e.

In this manner, the support 34e supports the lens 2e. In the example illustrated in FIG. 18, the lens 2e is fixed to the support 34e and is not configured to be driven. The support 34e can include a resin material, a metal material, or the like having a light shielding property. As used herein, the “light shielding property” means having a transmittance of preferably 40% or less with respect to light emitted from each of the first light-emitting part 10e-1 and the second light-emitting part 10e-2.

The lens 2e transmits the light emitted from each of the first light-emitting part 10e-1 and the second light-emitting part 10e-2. For example, the lens 2e can control the light distribution of the light emitted from each of the first light-emitting part 10e-1 and the second light-emitting part 10e-2.

In the example illustrated in FIG. 18, the lens 2e includes a first Fresnel lens 2e-1 and a second Fresnel lens 2e-2. The first Fresnel lens 2e-1 is disposed above the first light-emitting surface 11e-1. The second Fresnel lens 2e-2 is disposed above the second light-emitting surface 11e-2. In a case where there are a plurality of light-emitting parts corresponding to a plurality of respective Fresnel lenses as in the present embodiment, the center of the first Fresnel lens 2e-1 can overlap with the first light-emitting surface 11e-1 in a top view, and the center of the second Fresnel lens 2e-2 can overlap with the second light-emitting surface 11e-2 in a top view. In the example illustrated in FIG. 18, the center of the first Fresnel lens 2e-1 substantially coincides with the central axis 110-1 of the first light-emitting surface 11e-1, and the center of the second Fresnel lens 2e-2 substantially coincides with the central axis 110-2 of the second light-emitting surface 11e-2, but the configuration is not limited thereto. For example, the center of the first Fresnel lens 2e-1 can be shifted from the central axis 110-1 of the first light-emitting surface 11e-1, and the center of the second Fresnel lens 2e-2 can be shifted from the central axis 110-2 of the second light-emitting surface 11e-2. The first Fresnel lens 2e-1 and the second Fresnel lens 2e-2 of the lens 2e are integrally formed and connected to each other. The lens 2e can be manufactured by, for example, molding a light-transmissive resin material. As used herein, “light transmissive” means having a transmittance of preferably 60% or more with respect to the light emitted from each of the first light-emitting part 10e-1 and the second light-emitting part 10e-2.

The lens 2e does not necessarily include two Fresnel lenses, and can include one Fresnel lens or can include three or more Fresnel lenses. The arrangement of one or more Fresnel lenses can be determined as appropriate. For example, in a case where the first light-emitting part 10e-1 and the second light-emitting part 10e-2 are disposed close to each other, the lens 2e can include one Fresnel lens disposed above the first light-emitting part 10e-1 and the second light-emitting part 10e-2. Alternatively, in a case where the first light-emitting part 10e-1 and the second light-emitting part 10e-2 are separated from each other by a long distance, two Fresnel lenses can be disposed separated from each other so as to be respectively disposed above the first light-emitting part 10e-1 and the second light-emitting part 10e-2. Further, the lens 2e does not necessarily include a Fresnel lens. For example, the lens 2e can include one or more plano-convex lenses, one or more plano-concave lenses, one or more biconvex lenses, one or more meniscus lenses, or the like, or can include any combination thereof. Further, the light-emitting module-100e can include a drive mechanism for the lens 2e, and the lens 2e can be driven by the drive mechanism.

The first light-emitting part 10e-1 includes a first light-emitting element 12e-1 having a peak emission wavelength in a range of 410 nm or more and 490 nm or less, and a first light-transmissive member 14e-1 configured to be excited by light from the first light-emitting element 12e-1 and emit light. The second light-emitting part 10e-2 includes a second light-emitting element 12e-2 having a peak emission wavelength in a range of 410 nm or more and 460 nm or less, and a second light-transmissive member 14e-2 configured to be excited by light from the second light-emitting element 12e-2 and emit light. For example, each of the first light-transmissive member 14e-1 and the second light-transmissive member 14e-2 contains a phosphor. In the example illustrated in FIG. 18, the first light-emitting part 10e-1 includes a first covering member 15-1 disposed in contact with each of the first light-emitting element 12e-1 and the first light-transmissive member 14e-1. Further, the second light-emitting part 10e-2 includes a second covering member 15-2 disposed in contact with each of the second light-emitting element 12e-2 and the second light-transmissive member 14e-2.

As illustrated in FIG. 19, the first light-emitting part 10e-1 emits light in a region LSa (hereinafter can be referred to as a “light emission region of the first light-emitting part”) that is demarcated, in the chromaticity diagram of the CIE 1931 color space, by a first straight line connecting a first point at which x is 0.280 and y is 0.070 in the chromaticity coordinates and a second point at which x is 0.280 and y is 0.500 in the chromaticity coordinates, a second straight line connecting the second point and a third point at which x is 0.013 and y is 0.500 in the chromaticity coordinates, a purple boundary extending from the first point in a direction in which x decreases in the chromaticity coordinates, and a spectrum locus extending from the third point in a direction in which y decreases in the chromaticity coordinates.

The “purple boundary” is a locus connecting both the red end and the purple end of the spectrum locus formed in the chromaticity diagram. The colors on the purple boundary are colors that are not formed with monochromatic light (red to magenta), and colors that are formed by mixing colors. The “spectrum locus” means a curve obtained by connecting chromaticity points of monochromic (pure color) light in the chromaticity diagram. The chromaticity diagram of the CIE color space is defined by the Commission Internationale de l'Eclairage (CIE).
In the emission spectrum of the light-emitting module 100e, a light emission intensity ratio IPM/IPL of a light emission intensity IPM at a wavelength of 490 nm with respect to a light emission intensity IPL at a maximum peak emission wavelength of the first light-emitting element 12e-1 is in a range of 0.22 or more and 0.95 or less. Further, the second light-emitting part 10e-2 emits light having a color deviation duv in a range of −0.02 or more and 0.02 or less from the blackbody locus as measured according to JIS Z8725 when a correlated color temperature is in a range of 1,500 K or more and 8,000 K or less in the chromaticity diagram of the CIE1931 color space. The light-emitting module 100e can emit mixed-color light of light emitted from the first light-emitting part 10e-1 and light emitted from the second light-emitting part 10e-2.

In FIG. 18, the first light-transmissive member 14e-1 contains a first phosphor that is excited by light from the first light-emitting element 12e-1 and emits light. The first phosphor is at least one selected from the group consisting of an alkaline earth metal aluminate phosphor having a composition represented by the following formula (a1), a silicate phosphor having a composition represented by the following formula (a2), a silicate phosphor having a composition represented by the following formula (a3), and a rare earth aluminate phosphor having a composition represented by the following formula (a4).

Sr₄Al₁₄O₂₅:Eu (a1)

(Ca,Sr,Ba)₈MgSi₄O₁₆(F,Cl,Br)₂:Eu (a2)

(Ca,Sr,Ba)₂SiO₄:Eu (a3)

(Y,Gd,Tb,Lu)₃(Al,Ga)₅O₁₂:Ce (a4)

The second light-transmissive member 14e-2 contains a second phosphor that is excited by light from the second light-emitting element 12e-2 and emits light. The second phosphor includes at least one selected from a second phosphor A, a second phosphor B, and a second phosphor C. The second phosphor A is at least one selected from the group consisting of an alkaline earth metal aluminate phosphor having a composition represented by the following formula (a1′), a silicate phosphor having a composition represented by the following formula (a2′), a silicate phosphor having a composition represented by the following formula (a3′), a rare earth aluminate phosphor having a composition represented by the following formula (a4′). The second phosphor B is at least one selected from the group consisting of a silicon nitride phosphor having a composition represented by the following formula (b1), an alkaline earth silicon nitride phosphor having a composition represented by the following formula (b2), and a fluoride phosphor having a composition represented by the following formula (b3). The second phosphor C is at least one selected from the group consisting of a fluorogermanate phosphor having a composition represented by the following formula (C1) and an alkali nitride phosphor having a composition represented by the following formula (C2).

Sr₄Al₁₄O₂₅:Eu (a1′)

(Ca,Sr,Ba)₈MgSi₄O₁₆(F,Cl,Br)₂:Eu (a2′)

(Ca,Sr,Ba)₂SiO₄:Eu (a3′)

(Y,Gd,Tb,Lu)₃(Al,Ga)₅O₁₂:Ce (a4′)

(Ca,Sr)AlSiN₃:Eu (b1)

(Ca,Sr,Ba)₂Si₅N₈:Eu (b2)

K (Si,Ge,Ti)F₆:Mn (b3)

3.5 MgO·0.5 MgF₂·GeO₂:Mn (c1)

(Sr,Ca) (Li,Na,K)Al₃N₄:Eu (c2)

### Effects of Light-Emitting Module 100e

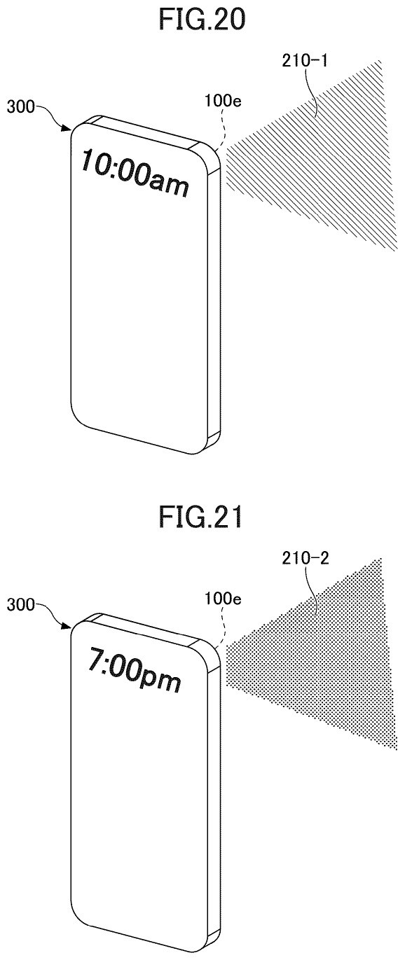

Next, effects of the light-emitting module 100e will be described with reference to FIG. 20 and FIG. 21. FIG. 20 is a schematic diagram illustrating a first example of light emitted from the light-emitting module 100e. FIG. 21 is a schematic diagram illustrating a second example of light emitted from the light-emitting module 100e.

In the example illustrated in FIG. 20 and FIG. 21, the light-emitting module 100e is mounted in a smartphone 300. The light-emitting module 100e can be used as a flash light source when a photograph is captured by an imaging device included in the smartphone 300 or a light source when a video is captured by the imaging device.

The light-emitting module 100e can emit light having substantially the same color temperature as the color temperature of sunlight at a desired time by controlling the output ratio of the first light-emitting part 10e-1 and the second light-emitting part 10e-2, for example. The imaging device included in the smartphone 300 can capture a photograph and a video having an atmosphere reflecting that of a desired time by using light emitted from the light-emitting module 100e.

For example, the imaging device included in the smartphone 300 can capture a photograph or a video at an actual time as if the photograph or the video were captured with external light of a desired time.

As illustrated in FIG. 20, in a case where a photograph is captured at 10:00 a.m., the smartphone 300 can cause the light-emitting module 100e to emit bluish white light 210-1 having substantially the same color temperature as the color temperature of sunlight at 10:00 a.m., so as to irradiate a subject with the bluish white light 210-1, and can cause the imaging device to photograph the subject. The light 210-1 indicated by diagonal hatching in FIG. 20 represents bluish white light. Further, as illustrated in FIG. 21, in a case where a photograph is captured at 7:00 p.m., the smartphone 300 can cause the light-emitting module 100e to emit orange light 210-2 having substantially the same color temperature as the color temperature of sunlight at 7:00 p.m., so as to irradiate a subject with the orange light 210-2, and can cause the imaging device to photograph the subject. The light 210-2 indicated by dot hatching in FIG. 21 represents orange light. Alternatively, in addition to the examples of FIG. 20 and FIG. 21, for example, the smartphone 300 can cause the light-emitting module 100e to emit light having substantially the same color temperature as the color temperature of sunlight at 10:00 a.m., which is different from the actual time of 7:00 p.m., so as to irradiate a subject with the light, and can cause the imaging device to photograph the subject. In this manner, the smartphone 300 can capture a photograph or a video as if the photograph or the video were captured with external light at a desired time different from the actual time.

An example of a method of emitting light having a color corresponding to a desired time by the light-emitting module 100e will be described. For example, correspondence information that defines a relationship between a time and the output ratio of the first light-emitting part 10e-1 and the second light-emitting part 10e-2 is stored in advance in a memory included in the smartphone 300, an external server that can communicate with the smartphone 300 via a network, or the like. The correspondence information can be obtained in advance by an experiment, a simulation, or the like. The smartphone 300 obtains information on a time desired by an operator through an operation input performed by the operator. The operator is a user or the like who uses the smartphone 300. The smartphone 300 can also obtain information on a time from a clock included in the smartphone 300 itself or an external device. The smartphone 300 obtains information on the output ratio of the first light-emitting part 10e-1 and the second light-emitting part 10e-2 by referring to the correspondence information, based on the obtained information on the time. The light-emitting module 100e can emit light having a color corresponding to the desired time based on the information on the output ratio obtained by the smartphone 300.

The light-emitting module 100e can also obtain information on the current location of the light-emitting module 100e by a global positioning system (GPS) or the like, and emit light having a color temperature adjusted to the color temperature of sunlight according to the latitude of the current location. In this case, the smartphone 300 can use correspondence information that defines a relationship among a time, the latitude of a current location, and the output ratio of the first light-emitting part 10e-1 and the second light-emitting part 10e-2. The smartphone 300 can capture a photograph or a video having an atmosphere reflecting that of a desired area on the earth and a desired time by using light having a color temperature adjusted to the color temperature of sunlight according to the latitude of the current location.

Although embodiments have been described in detail above, the above-described embodiments are non-limiting examples, and various modifications and substitutions can be made to the above-described embodiments without departing from the scope described in the claims. The numbers such as ordinal numbers and quantities used in the description of the embodiments are all exemplified to specifically describe the technique of the present disclosure, and the present disclosure is not limited to the exemplified numbers. In addition, the connection relationship between the components is illustrated for specifically describing the technique of the present disclosure, and the connection relationship for implementing the functions of the present disclosure is not limited thereto.

The light-emitting modules according to the present disclosure can emit color-adjusted light. Therefore, the light-emitting modules according to the present disclosure can be suitably used for lighting, camera flashes, vehicle headlights, and the like. However, the light-emitting modules according to the present disclosure are not limited to these applications.

According to an embodiment of the present disclosure, a light-emitting module that can emit light having a color adjusted to a predetermined color can be provided.

What is claimed is:

1. A light-emitting module comprising:
a light source comprising a plurality of light-emitting parts having respective light-emitting surfaces and including:
at least one first light-emitting part configured to emit light having a first chromaticity, and
at least one second light-emitting part configured to emit light having a second chromaticity different from the first chromaticity;
a lens configured to transmit light from the light source;
an actuator configured to change at least one of a relative position between the light source and the lens in a direction intersecting an optical axis of the lens or a relative inclination of the optical axis of the lens with respect to a corresponding one of the light-emitting surfaces; and
a controller configured to control light emission of each of the plurality of light-emitting parts and operation of the actuator such that:
the plurality of light-emitting parts are caused to emit light while at least one of the relative position or the relative inclination is changed by the actuator, and
there is at least partial overlap between (i) a position in an irradiation region on which light emitted from the first light-emitting part and transmitted through the lens is incident before a change in at least one of the relative position or the relative inclination and (ii) a position in the irradiation region on which light emitted from the second light-emitting part and transmitted through the lens is incident after the change in the at least one of the relative position or the relative inclination.

2. The light-emitting module according to claim 1, wherein the controller is configured to perform control such that there is at least partial overlap within a predetermined period of time for exposure between (i) the position in the irradiation region on which the light emitted from the first light-emitting part and transmitted through the lens is incident before a change in at least one of the relative position or the relative inclination is incident and (ii) the position in the irradiation region on which the light emitted from the second light-emitting part and transmitted through the lens is incident after the change in the at least one of the relative position or the relative inclination.

3. The light-emitting module according to claim 1, wherein the controller is configured to selectively cause at least one of the plurality of light-emitting parts to emit light, and configured to individually control an amount of light from each of the plurality of light-emitting parts by controlling at least one of a drive current, a drive voltage, or a light emission period of time of each of the plurality of light-emitting parts.

4. The light-emitting module according to claim 1, wherein, in a top view, the plurality of light-emitting parts are arranged in a grid pattern in a first direction and a second direction intersecting the first direction.

5. The light-emitting module according to claim 4, wherein the actuator is configured to move the lens with respect to the light source in the first direction or the second direction.

6. The light-emitting module according to claim 5, wherein a distance of the movement of the lens is a natural number multiple of a distance between centers of adjacent light-emitting parts of the plurality of light-emitting parts.

7. The light-emitting module according to claim 1, wherein the controller is configured to cause the actuator to change at least one of the relative position or the relative inclination a plurality of times within a predetermined period of time.

8. The light-emitting module according to claim 4, wherein:
the at least one first light-emitting part comprises two or more first light-emitting parts and/or the at least one second light-emitting part comprises two or more second light-emitting parts, and
the at least one first light-emitting part and the at least one second light-emitting part are alternately arranged in the first direction.

9. The light-emitting module according to claim 8, wherein the at least one first light-emitting part and the at least one second light-emitting part are alternately arranged in the second direction.

10. The light-emitting module according to claim 4, wherein:
the plurality of light-emitting parts include a plurality of first light-emitting parts and a plurality of second light-emitting parts, and
a first light-emitting part group of the plurality of first light-emitting parts and a second light-emitting part group of the plurality of second light-emitting parts are arranged adjacent to each other in the first direction.

11. The light-emitting module according to claim 10, wherein:
the first light-emitting part group a third light-emitting part group of the plurality of second light-emitting parts are arranged adjacent to each other in the second direction.

12. The light-emitting module according to claim 1, wherein, within a predetermined period of time during which the change in at least one of the relative position or the relative inclination is performed by the actuator one or more times, light from the light source after being transmitted through the lens is irradiated on (i) a first region, where the position on which light from the first light-emitting part is incident and the position on which light from the second light-emitting part is incident, and on (ii) a second region different from the first region, the second region comprising sub-regions each irradiated with either light from the first light-emitting part or light from the second light-emitting part.

13. The light-emitting module according to claim 12, wherein the controller is configured to cause a light-emitting part that is to emit light to the second region, among the plurality of light-emitting parts of the light source, not to emit the light.

14. The light-emitting module according to claim 1, wherein the plurality of light-emitting parts include at least one third light-emitting part configured to emit light having a third chromaticity other than the light having the first chromaticity and the light having the second chromaticity.

15. The light-emitting module according to claim 14, wherein the controller is configured to perform control such that there is at least partial overlap between (i) the position on which light emitted from the first light-emitting part and transmitted through the lens is incident before the change in the at least one of the relative position or the relative inclination and (ii) the position on which of light emitted from either the second light-emitting part or the third light-emitting part and transmitted through the lens is incident after the change of the at least one of the relative position or the relative inclination.

16. The light-emitting module according to claim 14, wherein, within a predetermined period of time during which at least one of the relative position or the relative inclination is changed by the actuator one or more times, light from the light source after being transmitted through the lens is emitted to (i) a third region where the position on which light from the first light-emitting part is incident, the position on which light from the second light-emitting part is incident, and the position on which light from the third light-emitting part is incident overlap with each other and to (ii) a fourth region different from the third region, the fourth region comprising sub-regions each irradiated with one or two of light from the first light-emitting part, light from the second light-emitting part, and light from third light-emitting part.

17. The light-emitting module according to claim 16, wherein the controller is configured to cause a light-emitting part that is to emit light to the fourth region, among the plurality of light-emitting parts of the light source, not to emit the light.

18. The light-emitting module according to claim 1, wherein
the light-emitting module is a flash light source used in an imaging device, and
the controller is configured to control the light emission of each of the plurality of light-emitting parts and the operation of the actuator within at least one of an imaging cycle or an exposure period of the imaging device.

19. A light-emitting module comprising:
a light source comprising a plurality of light-emitting parts having respective light-emitting surfaces and including:
at least one first light-emitting part configured to emit light having a first chromaticity, and
at least one second light-emitting part configured to emit light having a second chromaticity different from the first chromaticity;
a lens configured to transmit light from the light source;
an actuator configured to change at least one of a relative position between the light source and the lens in a direction intersecting an optical axis of the lens or a relative inclination of the optical axis of the lens with respect to a corresponding one of the light-emitting surfaces; and
a controller configured to control light emission of each of the plurality of light-emitting parts and operation of the actuator such that:
the plurality of light-emitting parts are caused not to emit light while one of the relative position or the relative inclination is changed by the actuator, and
there is at least partial overlap between (i) a position in an irradiation region on which light emitted from the first light-emitting part and transmitted through the lens is incident before a change in at least one of the relative position or the relative inclination and (ii) a position in the irradiation region on which light emitted from the second light-emitting part and transmitted through the lens is incident after the change in the at least one of the relative position or the relative inclination.
